(19) United States
(12) Patent Application Publication
(10) Pub. No.: US 2026/0344545 A1
(43) Pub. Date: Oct. 29, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Hyundong LEE, Suwon-si (KR); Youngmin KIM, Suwon-si (KR); Joon Seok OH, Suwon-si (KR)

(21) Appl. No.: 19/417,794

(22) Filed: Dec. 12, 2025

(30) Foreign Application Priority Data
Apr. 25, 2025 (KR) 10-2025-0054728

(51) Int. Cl. H10W 90/00; H10W 72/90; H10W 90/20; H10W 90/26

(52) U.S. Cl. CPC H10W 90/792; H10W 72/936; H10W 72/9445; H10W 72/963; H10W 90/26; H10W 90/297

(57) ABSTRACT

A lower chip includes a lower bonding pad on a back surface of a lower substrate, a lower dummy pad spaced apart from the lower bonding pad in a first direction and adjacent to an outer region in the lower substrate, and a lower bonding insulation layer surrounding at least a portion of the lower bonding pad and at least a portion of the lower dummy pad, an upper chip including an upper bonding pad that is on a front surface of an upper substrate and that includes a front surface facing the back surface of the lower substrate in a second direction, the front surface of the upper bonding pad being in contact with a back surface of the lower bonding pad, and an upper dummy pad spaced apart from the lower bonding pad in the first direction and adjacent to an outer region in the upper substrate.

### CROSS-REFERENCE TO RELATED APPLICATIONS

This application claims the benefit of Korean Patent Application No. 10-2025-0054728, filed on Apr. 25, 2025, in the Korean Intellectual Property Office, the disclosure of which is incorporated herein by reference in its entirety.

### BACKGROUND

With rapid development of an electronic industry and demand from users, an electronic device currently becomes smaller, more lightweight, and multifunctional. It may be desirable for the semiconductor device used in the electronic device to be smaller, more lightweight, and multifunctional.

### SUMMARY

In some examples, two or more types of semiconductor chips may be integrated in one semiconductor device. Through this, a size of the semiconductor device may be greatly reduced, and the semiconductor device may be allowed to have high capacity and multiple functions.

To achieve the high-capacity of the semiconductor device, the semiconductor chips may be stacked. A scheme of stacking the semiconductor chips may be largely classified into a die-to-wafer (D2W) bonding scheme and a wafer-to-wafer (W2W) bonding scheme. The D2W scheme is a scheme of stacking in units of a chip on a wafer, and the W2W scheme is a scheme of manufacturing a chip through a dicing process after stacking in units of a wafer.

In some aspects, implementations according to the present disclosure provide a semiconductor device for easily measuring a misalignment value generated in a process of bonding stacked semiconductor chips.

In some aspects, implementations according to the present disclosure provide a method of manufacturing the semiconductor device for easily measuring the misalignment value generated in the process of bonding the stacked semiconductor chips.

However, the goals to be achieved by implementations of the present disclosure are not limited to the objectives described above and other objects may be clearly understood from the following implementations by those skilled in the art.

In some aspects, the present disclosure provides a semiconductor device including a lower chip including a lower bonding pad on a back surface of a lower substrate, a lower dummy pad spaced apart from the lower bonding pad in a first direction and adjacent to an outer region in the lower substrate, and a lower bonding insulation layer surrounding at least a portion of the lower bonding pad and the lower dummy pad, an upper chip including an upper bonding pad that is on a front surface of an upper substrate and includes a front surface facing the back surface of the lower substrate in a second direction intersecting the back surface of the lower substrate and in contact with a back surface of the lower bonding pad, an upper dummy pad spaced apart from the lower bonding pad in the first direction and adjacent to an outer region in the upper substrate, and an upper bonding insulation layer surrounding at least a portion of the upper bonding pad and the upper dummy pad, and a molding layer surrounding the lower chip and the upper chip, and an outer side surface of the lower dummy pad and an outer side surface of the upper dummy pad are in contact with the molding layer.

In some aspects, the present disclosure provides a semiconductor device including a lower chip including a lower bonding pad disposed on a back surface of a lower substrate, a plurality of lower dummy pads spaced apart from the lower bonding pad in a first direction and adjacent to an outer region in the lower substrate, and a lower bonding insulation layer surrounding at least a portion of the lower bonding pad and the plurality of lower dummy pads, and an upper chip including an upper bonding pad that is disposed on a front surface of an upper substrate and includes a front surface facing the back surface of the lower substrate in a second direction intersecting the back surface of the lower substrate and in contact with a back surface of the lower bonding pad, a plurality of upper dummy pads spaced apart from the upper bonding pad in the first direction and adjacent to an outer region in the upper substrate, and an upper bonding insulation layer surrounding at least a portion of the upper bonding pad and the plurality of upper dummy pads, and outer side surfaces of the plurality of lower dummy pads are aligned with an outer side surface of the lower bonding insulation layer, and outer side surfaces of the plurality of upper dummy pads are aligned with an outer side surface of the upper bonding insulation layer.

In some aspects, the present disclosure provides a semiconductor device including a lower chip including a lower substrate, a lower bonding pad on a back surface of the lower substrate, a plurality of lower dummy pads spaced apart from the lower bonding pad in a first direction and adjacent to an outer region in the lower substrate, and a lower bonding insulation layer surrounding at least a portion of the lower bonding pad and the plurality of lower dummy pads, an upper chip including an upper substrate having a front surface facing a back surface of the lower bonding pad, an upper bonding pad that is on the front surface of the upper substrate and includes a front surface facing the back surface of the lower substrate in a second direction intersecting the back surface of the lower substrate and in contact with the back surface of the lower bonding pad, a plurality of upper dummy pads spaced apart from the upper bonding pad in the first direction and adjacent to an outer region in the upper substrate, and an upper bonding insulation layer surrounding at least a portion of the upper bonding pad and the plurality of upper dummy pads, and a molding layer surrounding the lower chip and the upper chip, and, when viewed in the second direction, the plurality of upper dummy pads includes a corner upper dummy pad disposed at a plurality of corner areas of the upper substrate and in contact with the molding layer, and a side upper dummy pad disposed between a pair of corner areas adjacent along an edge of the upper chip among the plurality of corner areas, and the plurality of lower dummy pads includes a corner lower dummy pad in contact with the molding layer and having a back surface in contact with a front surface of the corner upper dummy pad, and a side lower dummy pad having a back surface in contact with a front surface of the side upper dummy pad.

### BRIEF DESCRIPTION OF THE DRAWINGS

FIG. 1 is a diagram illustrating an example of a semiconductor device.

FIG. 2 is a diagram illustrating a cross section of an example of a semiconductor device, taken along line A-A′ of FIG. 1.

FIG. 3 is a diagram illustrating a cross section of an example of a semiconductor device, taken along line A-A′ of FIG. 1.

FIG. 4 is a diagram illustrating a cross section of an example of a semiconductor device, taken along line A-A′ of FIG. 1.

FIG. 5 is a diagram illustrating a cross section of an example of a semiconductor device, taken along line A-A′ of FIG. 1.

FIG. 6 is a diagram illustrating an example process of obtaining a misalignment value based on horizontal movement of an example of a stacked semiconductor chip.

FIG. 7 is a diagram illustrating an example process of obtaining a misalignment value based on rotational displacement of an example of a stacked semiconductor chip.

FIG. 8 is a diagram illustrating an example process of obtaining (i) a misalignment value based on horizontal movement of an example of a stacked semiconductor chip and (ii) a misalignment value based on rotational displacement of the stacked semiconductor chip.

FIG. 9 is a diagram illustrating an example of a semiconductor device.

FIG. 10 is a diagram illustrating an example of a semiconductor device.

FIG. 11 is a perspective diagram illustrating an example of a die-to-wafer bonding scheme.

FIG. 12 is a perspective diagram illustrating an example of a wafer-to-wafer bonding scheme.

FIG. 13 is a diagram illustrating a cross-sectional diagram of an example of a semiconductor device.

FIG. 14 is an enlarged diagram illustrating an enlargement of a section marked “CX” of FIG. 13.

FIG. 15 is a diagram illustrating an example of a semiconductor device.

FIG. 16 is a diagram illustrating a cross section taken along line B-B′ of FIG. 15.

FIG. 17 is a diagram illustrating a cross section of an example of a semiconductor device.

FIGS. 18A through 18G are cross-sectional diagrams sequentially illustrating example processes for manufacturing an example of a semiconductor device.

FIGS. 19A through 19J are cross-sectional diagrams sequentially illustrating example processes for manufacturing an example of a semiconductor device.

### DETAILED DESCRIPTION

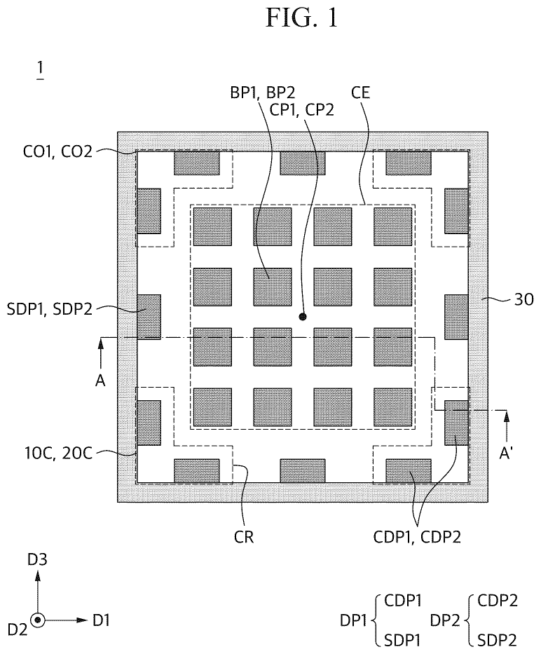

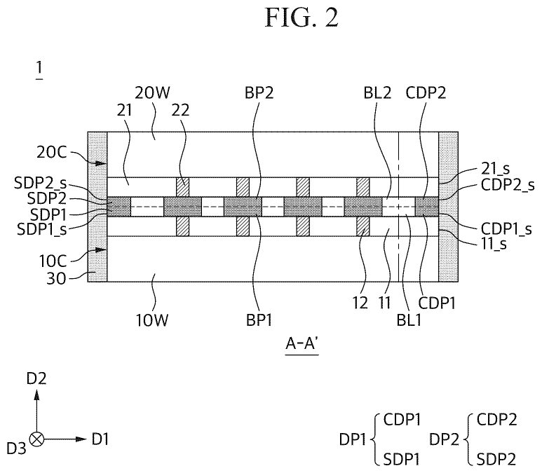

FIG. 1 is a schematic plan diagram for describing a semiconductor device according to some implementations of the present disclosure. FIG. 2 is an example diagram of a semiconductor device according to another example implementation of the present disclosure, which illustrates a cross section taken along line A-A′ of FIG. 1.

According to some implementations, a semiconductor device 1 may include a lower chip 10C, an upper chip 20C, and a molding layer 30. The semiconductor device 1 may have a structure in which the lower chip 10C and the upper chip 20C are hybrid-bonded together. The semiconductor device 1 may have a structure in which the upper chip 20C is stacked on and hybrid-bonded to the lower chip 10C.

As used herein, the term “on” when used to describe the positional relationship between component B and component A indicates that B is disposed above A, but allows for the possibility that one or more other components may be interposed between A and B.

According to some implementations, the lower chip 10C may include a lower substrate 10W, a lower wiring insulation layer 11, a lower via 12, a lower bonding insulation layer BL1, a lower bonding pad BP1, and a plurality of lower dummy pads DP1. According to some implementations, the upper chip 20C may include an upper substrate 20W, an upper wiring insulation layer 21, an upper via 22, an upper bonding insulation layer BL2, an upper bonding pad BP2, and a plurality of upper dummy pads DP2.

According to some implementations, a first direction D1 and a third direction D3 may be directions parallel to widest surfaces of the upper substrate 20W and the lower substrate 10W. A second direction D2 may be a direction intersecting the first direction D1 and the third direction D3. The second direction D2 may be a direction intersecting the widest surfaces of the upper substrate 20W and the lower substrate 10W. Hereinafter, the present disclosure will be described in a plan view intersecting the second direction D2.

According to some implementations, the lower chip 10C and the upper chip 20c may include a central area CE positioned near to centers CP1 and CP2. A plurality of lower bonding pads BP1 may be disposed in the central area CE of the lower chip 10C, and a plurality of upper bonding pads BP2 may be disposed in the central area CE of the upper chip 20C. FIG. 1 illustrates that the plurality of lower bonding pads BP1 and the plurality of upper bonding pads BP2 are disposed in a form of a grid, but it is merely an example. In some examples, disposition of the plurality of lower bonding pads BP1 and the plurality of upper bonding pads BP2 may vary depending on electrical wiring of the lower chip 10C and the upper chip 20C. The central area CE described in the present disclosure may be defined as an area other than an area in which a lower dummy pad DP1 and an upper dummy pad DP2 are disposed.

According to some implementations, the lower dummy pad DP1 may include a plurality of corner lower dummy pads CDP1 and a plurality of side lower dummy pads SDP1. The upper dummy pad DP2 may include a plurality of corner upper dummy pads CDP2 and a plurality of side upper dummy pads SDP2.

According to some implementations, the lower chip 10C and the upper chip 20c may include a corner area CR positioned near to corners CO1 and CO2. When viewed in the plan view intersecting the second direction D2, the lower chip 10C and the upper chip 20C may have a quadrangular shape. The corner area CR may be an area surrounding the corners CO1 and CO2 of the lower chip 10C and the upper chip 20C which have the quadrangular shape. The plurality of corner lower dummy pads CDP1 may be disposed in the corner area CR of the lower chip 10C, and the plurality of corner upper dummy pads CDP2 may be disposed in the corner area CR of the upper chip 20C. As an example, a pair of corner lower dummy pads CDP1 may be disposed in one corner area CR of the lower chip 10C. The pair of corner lower dummy pads CDP1 may be disposed to be spaced apart from and perpendicular to each other with a corner CO1 of the lower chip 10C in between. As an example, a pair of corner upper dummy pads CDP2 may be disposed in one corner area CR of the upper chip 20C. The pair of corner upper dummy pads CDP2 may be disposed to be spaced apart from and perpendicular to each other with a corner CO2 of the upper chip 20C in between.

According to some implementations, a corner lower dummy pad CDP1 may have a rectangular shape that has a length-wise side and a width-wise side when viewed in a horizontal view. A side surface of the corner lower dummy pad CDP1, which is parallel to a length direction thereof, may be disposed to be aligned with an outer side surface of the lower chip 10C. In the present disclosure, being aligned may mean that elements are disposed to form a substantially identical plane together within an allowed margin of error. Here, an identical plane may include a state in which respective reference surfaces of the elements form, through a dicing or polishing process in consideration of a step that may occur in a process, a continuous plane.

According to some implementations, when the upper chip 20C is rotated on and bonded to the lower chip 10C, a direction that outer side surfaces of the upper dummy pads DP2 corresponding to each other cross may be angled from a direction that an outer side surface of the lower dummy pad DP1 intersects. For example, a term “a side surface of a dummy pad intersecting the first direction D1” may include a case in which the upper chip 20C is not ideally and completely aligned with and bonded to the lower chip 10c and in which respective outer sides surfaces of the lower dummy pad DP1 and the upper dummy pad DP2 cross a direction angled from the first direction within a predetermined angle or less.

According to some implementations, similarly, a corner upper dummy pad CDP2 may have a rectangular shape that has a length-wise side and a width-wise side when viewed in a horizontal view. A side surface of the corner upper dummy pad CDP2, which is parallel to a length direction thereof, may be disposed to be aligned with a side surface of the upper chip 20C. However, the corner lower dummy pad CDP1 and the corner upper dummy pad CDP2 do not necessarily have the rectangular shape and may have various polygonal shapes depending on implementations.

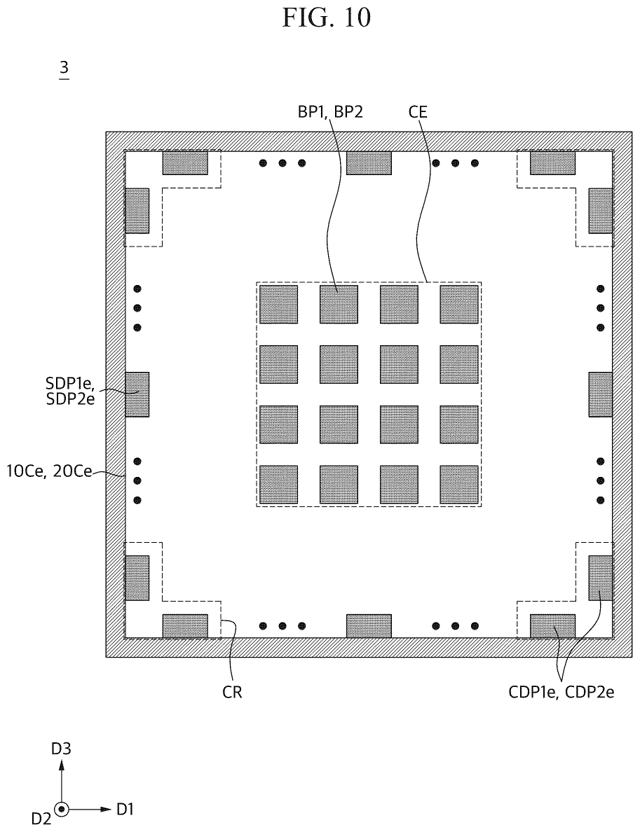

According to some implementations, the plurality of side lower dummy pads SDP1 may be disposed between a pair of corner areas CR adjacent along an edge of the lower chip 10C among a plurality of corner areas CR. In the present disclosure, one side lower dummy pad SDP1 is illustrated as being disposed between each pair of corner areas CR adjacent along an edge of the lower chip 10C. However, as illustrated in FIG. 10, the number of side lower dummy pads SDP disposed between each pair of corner areas CR adjacent along an edge of the lower chip 10C may vary depending on implementations.

According to some implementations, similarly, the plurality of side upper dummy pads SDP2 may be disposed between a pair of corner areas CR adjacent along an edge of the upper chip 20C among the plurality of corner areas CR. In the present disclosure, one side upper dummy pad SDP2 is illustrated as being disposed between each pair of corner areas CR adjacent along an edge of the upper chip 20C. However, as illustrated in FIG. 10, the number of side upper dummy pads SDP disposed between each pair of corner areas CR adjacent along an edge of the upper chip 20C may vary depending on implementations.

Hereinafter, a vertical structure of the lower chip 10C and the upper chip 20C of the semiconductor device 1, which is based on the second direction D2, will be described in detail with reference to FIG. 2.

In the present disclosure, a surface toward the upper chip 20C among surfaces of an element of the lower chip 10C may be defined as a back surface. Also, a surface toward the lower chip 10C among surfaces of an element of the upper chip 20C may be defined as a front surface. From a perspective of bonding the lower chip 10C and the upper chip 20C, the semiconductor device 1 may be a structure in which the back surface of the lower chip 10C and the front surface of the upper chip 20C are hybrid-bonded together. A surface opposite to the back surface among the surfaces of the element of the lower chip 10C may be defined as a front surface. A surface opposite to the front surface among the surfaces of the element of the upper chip 20C may be defined as a back surface. In order to assist in understanding the present disclosure, in the present disclosure, a surface intersecting the second direction D2 may be referred to as an upper surface, and a surface intersecting a reverse second direction −D2 may be referred to as a lower surface.

According to some implementations, the lower wiring insulation layer 11 and the lower via 12 may be disposed on a back surface of the lower substrate 10W. The lower bonding insulation layer BL1, the plurality of lower bonding pads BP1, the plurality of side lower dummy pads SDP1, and the plurality of corner lower dummy pads CDP1 may be disposed on a back surface of the lower wiring insulation layer 11. The upper wiring insulation layer 21 and the upper via 22 may be disposed on a front surface of the lower substrate 20W. The upper bonding insulation layer BL2, the plurality of upper bonding pads BP2, the plurality of side upp23 dummy pads SDP2, and the plurality of corner upper dummy pads CDP2 may be disposed on a front surface of the upper wiring insulation layer 21.

According to some implementations, the lower substrate 10W and the upper substrate 20W may be formed based on a group IV material wafer such as a silicon wafer or a group III-V compound wafer. The lower substrate 10W and the upper substrate 20W may be formed of a monocrystalline silicon wafer such as a monocrystalline silicon wafer.

According to some implementations, the lower substrate 10W and the upper substrate 20W may not be limited to the monocrystalline wafer. Various wafers such as an epitaxial wafer, a polished wafer, an annealed wafer, and a silicon-on-insulator (SOI) wafer may be used as the lower substrate 10W and the upper substrate 20W. The epitaxial wafer may be a wafer in which a crystalline material is grown on a monocrystalline silicon substrate. In addition, in some implementations, the lower substrate 10W and the upper substrate 20W may be a glass substrate.

According to some implementations, the lower substrate 10W and the upper substrate 20W may include a well doped with an impurity or a structure doped with an impurity. The lower substrate 10W and the upper substrate 20W may include various element isolation structures such as a shallow trench isolation (STI) structure.

According to some implementations, the lower chip 10C and the upper chip 20C each may include various types of individual devices. The individual devices may include various microelectronic devices, for example, a metal-oxide-semiconductor filed effect transistor (MOFSET) such as a complementary metal-insulator-semiconductor (CMOS) transistor, a system large-scale integration (LSI) device, an image sensor such as an CMOS imaging sensor (CIS), a micro-electro-mechanical system (MEMS), an active element, a passive element, or the like. In some examples, the individual devices may be formed in the lower substrate 10W and the upper substrate 20W.

According to some implementations, the lower chip 10C and the upper chip 20C each may be at least one of a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, and a resistive random access memory (RRAM) chip.

According to some implementations, the lower wiring insulation layer 11 may be disposed to surround the lower via 12 while insulating the lower via 12. The upper wiring insulation layer 21 may be disposed to surround the upper via 22 while insulating the upper via 22. The lower bonding insulation layer BL1 may be disposed to surround the lower bonding pad BP1 and the lower dummy pad DP1 while insulating the lower bonding pad BP1 and the lower dummy pad DP1. The upper bonding insulation layer BL2 may be disposed to surround the upper bonding pad BP2 and the upper dummy pad DP2 while insulating the upper bonding pad BP2 and the upper dummy pad DP2.

According to some implementations, the lower via 12, the lower bonding pad BP1, the lower dummy pad DP1, the upper via 22, the upper bonding pad BP2, and the upper dummy pad DP2 may include a metallic layer, for example, copper, aluminum, silver, cobalt, ruthenium, or an alloy thereof. The lower wiring insulation layer 11, the upper wiring insulation layer 21, the lower boning insulation layer BL1, and the upper bonding insulation layer BL2 may be formed as dielectric layers. The lower wiring insulation layer 11, the upper wiring insulation layer 21, the lower bonding insulation layer BL1, and the upper bonding insulation layer BL2 may be formed of silicon oxide (SiO₂), carbon-doped silicon oxide (C-doped SiO₂), silicon nitride (SiN), silicon carbonitride (SiCN), a polymer, or the like.

According to some implementations, as illustrated in FIGS. 1 and 2, the lower bonding pad BP1 and the upper bonding pad BP2 in the central area CE may be disposed to be overlap in the second direction D2. As described above, the semiconductor device 1 may have the structure in which the upper chip 20C is stacked on and bonded to the lower chip 10C. The lower bonding pad BP1 and the upper bonding pad BP2 may be directly bonded to each other by a metal-metal bonding scheme. For example, the lower bonding pad BP1 and the upper bonding pad BP2 may be bonded to each other between the lower substrate 10W and the upper substrate 20W by copper (Cu)-copper (Cu) hybrid bonding. When formed of a metal other than copper, the lower bonding pad BP1 and the upper bonding pad BP2 may be bonded to each other by other metal-metal hybrid bonding.

According to some implementations, the lower bonding insulation layer BL1 and the upper bonding insulation layer BL2 may be directly bonded to each other by a dielectric-dielectric bonding scheme. The lower bonding insulation layer BL1 and the upper bonding insulation layer BL2 may include an identical insulation material to form a bonding structure. The lower bonding insulation layer BL1 and the upper bonding insulation layer BL2 may be bonded together by a high-temperature annealing process in a state of being in contact with each other. At this point, the bonding structure may have higher bonding strength by a covalent bond.

According to some implementations, the plurality of lower dummy pads DP1 and the plurality of upper dummy pads DP2 also may be directly bonded to each other by a metal-metal bonding scheme. A back surface of the lower dummy pad DP1 may be in contact with a front surface of the upper dummy pad DP2. Specifically, the corner lower dummy pad CDP1 and the corner upper dummy pad CDP2 also may be directly bonded to each other by a metal-metal bonding scheme. According to some implementations, a side lower dummy pad SDP1 and a side upper dummy pad SDP2 may be directly bonded to each other by a metal-metal bonding scheme. Since a bonding scheme for the plurality of lower dummy pads DP1 and the plurality of upper dummy pads DP2 is similar to a bonding scheme for the lower bonding pad BP1 and the upper bonding pad BP2, a detailed description thereof will be omitted.

According to some implementations, the molding layer 30 may be disposed to surround the lower chip 10C and the upper chip 20C. As illustrated in FIGS. 1 and 2, outer side surfaces CDP1_s of the plurality of corner lower dummy pads CDP1, which intersect a horizontal direction D1 and/or D3, may be in contact with the molding layer 30. Since being exposed to an outside of the lower chip 10C and not being in contact with the lower bonding insulation layer BL1, the outer side surfaces CDP1_s of the plurality of corner lower dummy pads CDP1 may be in contact with the molding layer 30. Outer side surfaces CDP2_s of the plurality of corner upper dummy pads CDP2, which intersect the first direction D1, may be in contact with the molding layer 30. Since being exposed to an outside of the upper chip 20C and not being in contact with the upper bonding insulation layer BL2, the outer side surfaces CDP2_s of the plurality of corner upper dummy pads CDP2 may be in contact with the molding layer 30.

According to some implementations, similarly, outer side surfaces SDP1_s of the plurality of side lower dummy pads SDP1, which intersect the horizontal direction D1 and/or D3, may be in contact with the molding layer 30. Since being exposed to the outside of the lower chip 10C and not being in contact with the lower bonding insulation layer BL1, the outer side surfaces SDP1_s of the plurality of side lower dummy pads SDP1 may be in contact with the molding layer 30. Outer side surfaces SDP2_s of the plurality of side upper dummy pads SDP2, which intersect the first direction D1, may be in contact with the molding layer 30. Since being exposed to the outside of the upper chip 20C and not being in contact with the upper bonding insulation layer BL2, the outer side surfaces SDP2_s of the plurality of side upper dummy pads SDP2 may be in contact with the molding layer 30. As an example, the molding layer 30 may include an epoxy resin. The molding layer 30 may be mixed with a filler. The filler may be formed of, for example, silica. The filler may have a size, for example, less than or equal to 0.1 to a few micrometers (μm) and may have a size of approximately 0.3 to 1 μm on average.

According to some implementations, side surfaces opposite to the outer side surfaces CDP1_s of the plurality of corner lower dummy pads CDP1 and side surfaces opposite to the outer side surfaces SDP1_s of the plurality of side lower dummy pads SDP1 may be in contact with the lower bonding insulation layer BL1. According to some implementations, side surfaces opposite to the outer side surfaces CDP2_s of the plurality of corner upper dummy pads CDP2 and side surfaces opposite to the outer side surfaces SDP2_s of the plurality of side upper dummy pads SDP2 may be in contact with the upper bonding insulation layer BL2.

According to some implementations, an outer side surface CDP1_s of the corner lower dummy pad CDP1 and an outer side surface SDP1_s of the side lower dummy pad SDP1 may be aligned with an outer side surface 11_s of the lower wiring insulation layer 11. According to some implementations, an outer side surface CDP2_s of the corner upper dummy pad CDP2 and an outer side surface SDP2_s of the side upper dummy pad SDP2 may be aligned with an outer side surface 21_s of the upper wiring insulation layer 21. As described above, being aligned may mean that elements are disposed to form a substantially identical plane together within an allowed margin of error.

In a process in which the upper chip 20C is stacked on the lower chip 10C in a hybrid bonding scheme, misalignment of the lower chip 10C and the upper chip 20C may occur, which will be described in detail below. The lower dummy pad DP1 and the upper dummy pad DP2 may be exposed to outsides of the lower chip 10C and the upper chip 20C, so that an index for measuring a value of the misalignment in real time in a process of hybrid bonding may be provided. Specifically, the corner lower dummy pad CDP1 and the corner upper dummy pad CDP2 may show an index for measuring a misalignment value based on rotational displacement of the upper chip 20C on the lower chip 10C. The side lower dummy pad SDP1 and the side upper dummy pad SDP2 may show an index for measuring a misalignment value based on horizontal movement (in directions D1 and/or D3) of the upper chip 20C on the lower chip 10C.

According to some implementations, the lower via 12 may be in contact with a front surface of the lower bonding pad BP1 to be electrically connected thereto. The lower via 12 may provide an electrical connection passage between the lower bonding pad BP1 and an individual device in the lower substrate 10W. The upper via 22 may be in contact with a back surface of the upper bonding pad BP2 to be electrically connected thereto. The upper via 22 may provide an electrical connection passage between the upper bonding pad BP2 and an individual device in the upper substrate 20W.

According to some implementations, an entire front surface of the lower dummy pad DP1 may be in contact with the lower wiring insulation layer 11. Since being not connected to the lower via 12, the lower dummy pad DP1 may not be electrically connected to the individual device in the lower substrate 10W. Also, since being not connected to the upper via 22, the lower dummy pad DP1 may be electrically insulated from the upper chip 20C. According to some implementations, an entire front surface of the lower dummy pad DP1 may be in contact with the lower wiring insulation layer 11.

According to some implementations, an entire back surface of the upper dummy pad DP2 may be in contact with the upper wiring insulation layer 21. Since being not connected to the upper via 22, the upper dummy pad DP2 may not be electrically connected to the individual device in the upper substrate 20W. Also, since being not connected to the lower via 22, the upper dummy pad DP2 may be electrically insulated from the lower chip 10C. The entire back surface of the upper dummy pad DP2 may be in contact with the upper wiring insulation layer 21.

According to some implementations, a width along a major axis of the lower dummy pad DP1 and a width along a major axis of the upper dummy pad DP2 may within a range from 5 μm to 50 μm. The width along the major axis may refer to a longest width of each of the lower dummy pad DP1 and the upper dummy pad DP2. When widths along major axes of the lower dummy pad DP1 and the upper dummy pad DP2 are less than 5 μm, an area sufficient for bonding thereof to each other may not be secured. When the widths along the major axes of the lower dummy pad DP1 and the upper dummy pad DP1 are greater than 50 μm, an electrical short circuit between dummy pads or bonding pads spaced apart along the horizontal direction D1 and/or D3 may occur.

Also, the lower dummy pad DP1 and the upper dummy pad DP2 may be disposed in an outer region in the lower bonding insulation layer BL1 and the upper bonding insulation layer BL2, so that warpage caused by thermal deformation of the lower bonding insulation layer BL1 and the upper bonding insulation layer BL2 may be mitigated. Coefficients of thermal expansion of the lower dummy pad DP1 and the upper dummy pad DP2 may be less than coefficients of thermal expansion of the lower bonding insulation layer BL1 and the upper bonding insulation layer BL2.

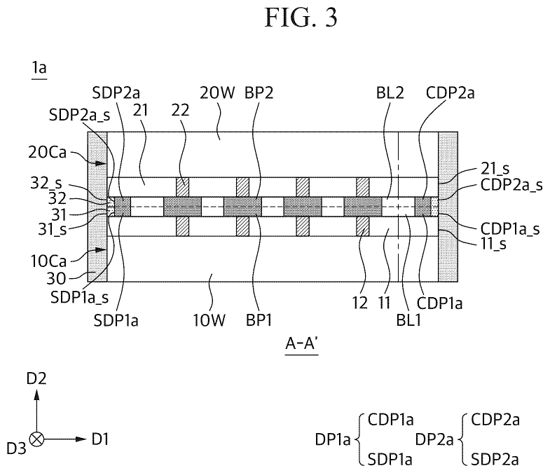

FIG. 3 is an example diagram of a semiconductor device according to another implementation of the present disclosure, which illustrates a cross section taken along line A-A′ of FIG. 1.

When compared to the semiconductor device 1 illustrated in FIGS. 1 and 2, a semiconductor device 1a illustrated in FIG. 3 may be similar or approximately identical thereto, excluding a point that a lower oxide film 31 is disposed on outer side surfaces of a plurality of lower dummy pads DP1a and a point that an upper oxide film 32 is disposed on outer side surfaces of a plurality of upper dummy pads DP2a. Thus, a description of the element described above with reference to FIGS. 1 and 2 will be omitted or simplified below.

According to some implementations, the lower oxide film 31 may be disposed on an outer side surface SDP1a_s of a side lower dummy pad SDP1a and an outer side surface CDP1a_s of a corner lower dummy pad CDP1a. The lower oxide film 31 may be a film formed as the side lower dummy pad SDP1a and the corner lower dummy pad CDP1a are exposed to air and oxidized. As shown in some implementations illustrated in FIG. 3, the side lower dummy pad SDP1a and the corner lower dummy pad CDP1a may be exposed to an outside of a lower chip 10Ca. Oxygen in an atmosphere may trigger an oxidation reaction with the side lower dummy pad SDP1a and the corner lower dummy pad CDP1a. The lower oxide film 31 may be a film distinguished from the lower bonding insulation layer BL1.

According to some implementations, similarly, the upper oxide film 32 may be disposed on an outer side surface SDP2a_s of a side upper dummy pad SDP2a and an outer side surface CDP2a_s of a corner upper dummy pad CDP2a. The upper oxide film 32 may be a film formed as the side upper dummy pad SDP2a and the corner upper dummy pad CDP2a are exposed to air and oxidized. In a case of the upper oxide film 32 also, as shown in some implementations illustrated in FIG. 2, the side upper dummy pad SDP2a and the corner upper dummy pad CDP2a may be exposed to an outside of an upper chip 20Ca. Oxygen in the atmosphere may trigger an oxidation reaction with the side upper dummy pad SDP2a and the corner upper dummy pad CDP2a.

According to some implementations, an outer side surface 31_S of the lower oxide film 31 and an outer side surface 32_s of the upper oxide film 32 may be in contact with the molding layer 30. Since the lower oxide film 31 is exposed to the outside of the lower chip 10Ca, and since the upper oxide film 32 is exposed to the outside of the upper chip 20Ca, the molding layer 30 which surrounds the lower chip 10Ca and the upper chip 20Ca the outer side surface 31_s of the lower oxide film 31 and the outer side surface 32_s of the upper oxide film 32.

According to some implementations, an entire front surface of a lower dummy pad DP1a may be in contact with the lower wiring insulation layer 11. Since being not connected to the lower via 12, the lower dummy pad DP1a may not be electrically connected to an individual device in the lower substrate 10W. In other words, the lower dummy pad DP1a may be electrically insulated from the upper chip 20C. Thus, although a portion of the lower dummy pad DP1a is oxidized, reliability of electrical wiring between the lower chip 10Ca and the upper chip 20Ca may not be decreased.

According to some implementations, an entire back surface of an upper dummy pad DP2a may be in contact with the upper wiring insulation layer 21. Since being not connected to the upper via 22, the upper dummy pad DP2a may not be electrically connected to an individual device in the upper substrate 20W. In other words, the upper dummy pad DP2a may be electrically insulated from the lower chip 10C. Thus, although a portion of the upper dummy pad DP2a is oxidized, the reliability of the electrical wiring between the lower chip 10Ca and the upper chip 20Ca may not be decreased.

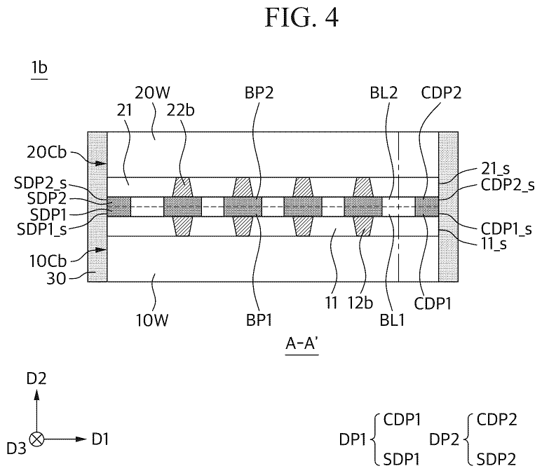

FIG. 4 is an example diagram of a semiconductor device according to another implementation of the present disclosure, which illustrates a cross section taken along line A-A′ of FIG. 1.

When compared to the semiconductor device 1 illustrated in FIGS. 1 and 2, a semiconductor device 1b illustrated in FIG. 4 may be similar or approximately identical thereto, excluding a point that a lower via 12b and an upper via 22b have a tapered shape. Thus, a description of the element described above with reference to FIGS. 1 and 2 will be omitted or simplified below.

According to some implementations, the lower via 12b may have the tapered shape of which a width in the horizontal direction D1 and/or D3 is widened as approaching an upper chip 20Cb. Due to a limitation on a process, a width of the lower via 12b may not be gradually increased as approaching the upper chip 20Cb. Specifically, a width of the lower via 12b at a back surface of the lower wiring insulation layer 11 may be greater than a width of the lower via 12b at a front surface of the lower wiring insulation layer 11.

According to some implementations, the upper via 22b may have the tapered shape of which the width in the horizontal direction D1 and/or D3 is widened as approaching a lower chip 10Cb. Due to a limitation on a process, a width of the upper via 22b may not be gradually increased as approaching the lower chip 20Cb. Specifically, a width of the upper via 22b at a back surface of the upper wiring insulation layer 21 may be greater than a width of the upper via 22b at a front surface of the upper wiring insulation layer 21.

In some implementations, in contrast, the lower via 12b may have a tapered shape of which a width in the horizontal direction D1 and/or D3 is narrowed as approaching the upper chip 20Cb. Also, the upper via 22b may have a tapered shape of which a width in the horizontal direction D1 and/or D3 is narrowed as approaching the lower chip 10Cb.

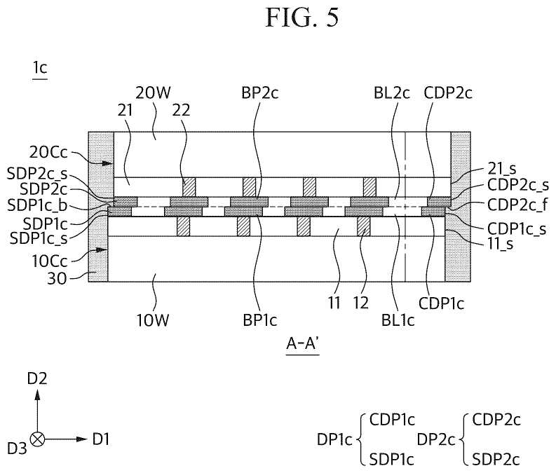

FIG. 5 is an example diagram of a semiconductor device according to another example of the present disclosure, which illustrates a cross section taken along line A-A′ of FIG. 1.

When compared to the semiconductor device 1 illustrated in FIGS. 1 and 2, a semiconductor device 1c illustrated in FIG. 5 may be similar or approximately identical thereto, excluding a point that a lower bonding pad BP1c and an upper bonding pad BP2c are offset from each other in the horizontal direction D1 and/or D3 and a point that a lower dummy pad DP1c and an upper dummy pad DP2c are offset from each other in the horizontal direction D1 and/or D3. Thus, a description of the element described above with reference to FIGS. 1 and 2 will be omitted or simplified below.

According to some implementations, the lower bonding pad BP1c and the upper bonding pad BP2c may be offset from each other in the first direction D1. In some implementations, the lower bonding pad BP1c and the upper bonding pad BP2c may be offset in the third direction D3 as well as the first direction D1.

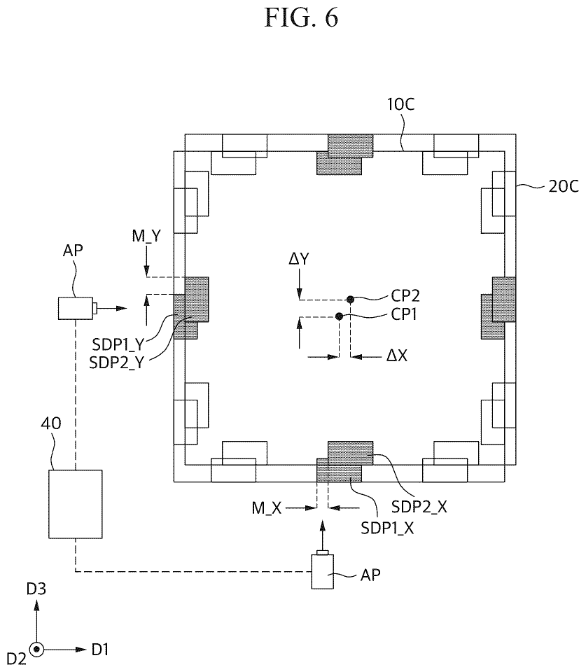

As illustrated in FIGS. 6 through 8, in a process in which an upper chip 20Cc is stacked on a lower chip 10Cc in a hybrid bonding scheme, misalignment of the lower chip 10Cc and the upper chip 20Cc may occur. In this case, the lower bonding pad BP1c and the upper bonding pad BP2c may be hybrid-bonded in a state of being offset from each other in the horizontal direction D1 and/or D3.

According to some implementations, the lower dummy pad DP1c may include a corner lower dummy pad CDP1c and a side lower dummy pad SDP1c, and the upper dummy pad DP2c may include a corner upper dummy pad CDP2c and a side upper dummy pad SDP2c.

According to some implementations, the side lower dummy pad SDP1c and the side upper dummy pad SDP2c may be offset from each other in the horizontal direction D1 and/or D3. The corner lower dummy pad CDP1c and the corner upper dummy pad CDP2c also may be offset from each other in the horizontal direction D1 and/or D3.

According to some implementations, an outer side surface SDP1c_s of the side lower dummy pad SDP1c may not be aligned with the outer side surface 21_s of the upper wiring insulation layer 21 and may be offset in the horizontal direction D1 and/or D3. An outer side surface SDP2c_s of the side upper dummy pad SDP2c may not be aligned with the outer side surface 11_s of the lower wiring insulation layer 11 and may be offset in the horizontal direction D1 and/or D3.

According to some implementations, an outer side surface CDP1c_s of the corner lower dummy pad CDP1c may not be aligned with the outer side surface 21_s of the upper wiring insulation layer 21 and may be offset in the horizontal direction D1 and/or D3. An outer side surface CDP2c_s of the corner upper dummy pad CDP2c may not be aligned with the outer side surface 11_s of the lower wiring insulation layer 11 and may be offset in the horizontal direction D1 and/or D3.

According to some implementations, a portion of a back surface SDP1c_b of the side lower dummy pad SDP1c may be in contact with the molding layer 30. A portion of a front surface CDP2c_f of the corner upper dummy pad CDP2c may be in contact with the molding layer 30. The portion of the back surface SDP1c_b of the side lower dummy pad SDP1c, which is in contact with the molding layer 30, may be an area not overlapping the side upper dummy pad SDP2c in the second direction D2. The portion of the front surface CDP2c_f of the corner upper dummy pad CDP2c, which is in contact with the molding layer 30, may be an area not overlapping the corner lower dummy pad CDP1c in the second direction D2.

A state in which a front surface of the side upper dummy pad SDP2c is in contact with the molding layer 30 has not been illustrated in the cross section illustrated in FIG. 5. However, a structure in which the front surface of the side upper dummy pad SDP2c disposed to right of the upper chip 20Cc when viewed in a plan view such as an illustration in FIG. 1 is in contact with the molding layer 30 may be a configuration adequately inferable by those skilled in the art depending on a technical level thereof when FIG. 5 is referenced.

Similarly, a state in which a back surface of the corner lower dummy pad CDP1c is in contact with the molding layer 30 has not been illustrated in the cross section illustrated in FIG. 5. However, a structure in which the back surface of the corner lower dummy pad CDP1c disposed to left of the lower chip 10Cc when viewed in the plan view such as the illustration in FIG. 1 is in contact with the molding layer 30 may be a configuration adequately inferable by those skilled in the art depending on a technical level thereof when FIG. 5 is referenced.

FIG. 6 is a schematic plan diagram for describing a process of obtaining a misalignment value based on horizontal movement of a stacked semiconductor chip.

In order to assist in understanding the present disclosure, side lower dummy pads SDP1_X and SDP1_Y and side upper dummy pads SDP2_X and SDP2_Y will be mainly described.

FIG. 6 illustrate, in a view intersecting the second direction D2, a case in which the upper chip 20C is offset in the first direction D1 and the third direction D3 and stacked on the lower chip 10C. In a horizontal view intersecting the second direction D2, a center CP2 of the upper chip 20C may be offset from a center CP1 of the lower chip 10C in the first direction D1 and the third direction D3. A distance by which the center CP2 of the upper chip 20C is offset from the center CP1 of the lower chip 10C may be a misalignment value based on movement of the upper chip 20C on the lower chip 10C in the horizontal direction D1 and/or D3.

According to some implementations, the center CP2 of the upper chip 20C may be offset from the center CP1 of the lower chip 10C by a first misalignment value ΔX in the first direction D1. The first misalignment value ΔX may be obtained by using a first side lower dummy pad SDP1_X aligned along a surface, which is parallel to the first direction D1, of the lower chip 10C and a first side upper dummy pad SDP2_X aligned along a surface, which is parallel to the first direction D1, of the upper chip 20C. The first misalignment value ΔX may be obtained by measuring a distance by which the first side upper dummy pad SDP2_X is offset from the first side lower dummy pad SDP1_X.

According to some implementations, a measurement device AP may measure a first position, which is in the first direction D1, of the first side lower dummy pad SDP1_X which is exposed at a side surface, which intersects the third direction D3, of the lower chip 10C. The first position may be a position of an outermost edge of the exposed first side lower dummy pad SDP1_X, which is in the first direction D1. Also, the measurement device AP may measure a second position, which is in the first direction D1, of the first side upper dummy pad SDP2_X which is exposed at a side surface, which intersects the third direction D3, of the upper chip 20C. The second position may be a position of an outermost edge of the exposed first side upper dummy pad SDP2_X, which is in the first direction D1. However, the first position and the second position are not necessarily limited to the above description. Positions of points corresponding to each other for position comparison between the first side lower dummy pad SDP1_X and the first side upper dummy pad SDP2_X may suffice therefor.

For example, the measurement device AP may be an optical measurement device including a camera module for photographing an object, an image processing unit that calculates a length of the object based on an image obtained by the photographing by the camera module, and a control unit that controls the above-described entire operations. However, an example of the measurement device AP is not limited to the above description.

According to some implementations, a difference between a first position value and a second position value may be the first misalignment value ΔX. The first misalignment value ΔX may be a misalignment value based on movement of the upper chip 20C on the lower chip 10C in the first direction D1. A controller 40 may receive data on the first misalignment value ΔX from the measurement device AP. In some implementations, the measurement device AP may transmit data on the first position value and the second position value to the controller 40. At this point, the controller 40 may obtain the first misalignment value ΔX through the difference between the first position value and the second position value.

According to some implementations, an operation of the measurement device AP may be controlled by an instruction from the controller 40. The controller 40 may be implemented as hardware, software, or any combination thereof. For example, the controller 40 may be a computing device such as a workstation computer, a desktop computer, a laptop computer, or a tablet computer. For example, the controller may include a memory device such as a read only memory (ROM) or a random access memory (RAM) and a processor configured to perform predetermined calculation and an algorithm, for example, a microprocessor, a central processing unit (CPU), a graphics processing unit (GPU), or the like. In addition, the controller 40 may include a receiver and a transmitter for receiving and transmitting an electrical signal.

According to some implementations, the center CP2 of the upper chip 20C may be offset from the center CP1 of the lower chip 10C by a second misalignment value ΔY in the third direction D3. The second misalignment value ΔY may be obtained by using a second side lower dummy pad SDP1_Y aligned along a surface, which is parallel to the third direction D3, of the lower chip 10C and a second side upper dummy pad SDP2_Y aligned along a surface, which is parallel to the third direction D3, of the upper chip 20C. The second misalignment value ΔY may be obtained by measuring a distance by which the second side upper dummy pad SDP2_Y is offset from the second side lower dummy pad SDP1_Y.

According to some implementations, the measurement device AP may measure a third position, which is in the third direction D3, of the second side lower dummy pad SDP1_Y which is exposed at a side surface, which intersects the first direction D1, of the lower chip 10C. The third position may be a position of an outermost edge of the exposed second side lower dummy pad SDP1_Y, which is in the third direction D3. Also, the measurement device AP may measure a fourth position, which is in the third direction D3, of the second side upper dummy pad SDP2_Y which is exposed at a side surface, which intersects the first direction D1, of the upper chip 20C. The fourth position may be a position of an outermost edge of the exposed second side upper dummy pad SDP2_Y, which is in the third direction D3. However, the third position and the fourth position are not necessarily limited to the above description. Positions of points corresponding to each other for position comparison between the second side lower dummy pad SDP1_Y and the second side upper dummy pad SDP2_Y may suffice therefor.

According to some implementations, a difference between a third position value and a fourth position value may be the second misalignment value ΔY. The second misalignment value ΔY may be a misalignment value based on movement of the upper chip 20C on the lower chip 10C in the third direction D3. The controller 40 may receive data on the second misalignment value ΔY from the measurement device AP. In some implementations, the measurement device AP may transmit data on the third position value and the fourth position value to the controller 40. At this point, the controller 40 may obtain the second misalignment value ΔY through the difference between the third position value and the fourth position value.

Through the above-described series of processes, the misalignment value based on the movement of the upper chip 20C in the horizontal direction D1 and/or D3 on the lower chip 10C may be obtained.

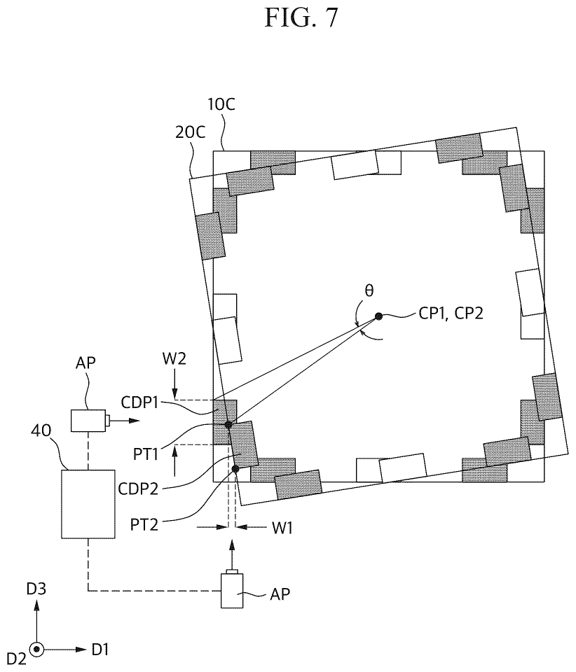

FIG. 7 is a schematic plan diagram for describing a process of obtaining a misalignment value based on rotational displacement of a stacked semiconductor chip.

In order to assist in understanding the present disclosure, the corner lower dummy pad CDP1 and the corner upper dummy pad CDP2 will be mainly described.

FIG. 7 illustrates, in a view intersecting the second direction D2, a case in which the upper chip 20C is rotated and stacked on the lower chip 10C. The upper chip 20C may merely rotate on a position thereof and may not move in the horizontal direction D1 and/or D3. Thus, the center CP1 of the lower chip 10C and the center CP2 of the upper chip 20C may overlap in the second direction D2. The upper chip 20C may be rotated by a predetermined angle θ and stacked on the lower chip 10C. The predetermined angle θ may be a misalignment value based on rotational displacement of the upper chip 20C on the lower chip 10C.

According to some implementations, the angle θ may be obtained by using the corner lower dummy pad CDP1 and the corner upper dummy pad CDP2 which are disposed in the corner area (see FIG. 1). At this point, a width along a major axis of the corner lower dummy pad CDP1 and a width along a major axis of the corner upper dummy pad CDP2 may be equal to each other. Here, a process of obtaining the angle θ will be described in detail.

In the present example, a process of obtaining the angle θ by using the corner lower dummy pad CDP1 and the corner upper dummy pad CDP2 in the corner area CR which is positioned at a lower left portion in the view intersecting the second direction D2 will be described. In a way identical to the following description, the angle θ may be obtained by using another corner lower dummy pad CDP1 and another corner upper dummy pad CDP2 in another corner area CR.

According to some implementations, the measurement device AP may be aligned to face a side surface of the lower chip 10C, which intersects the third direction D3. Since the upper chip 20C is rotated by the angle θ, the measurement device AP may be arranged obliquely toward a side surface of the upper chip 20C.

According to some implementations, the measurement device AP may obtain a first width W1 of an exposed area of the corner upper dummy pad CDP2, which is in the first direction D1. The exposed area may be a side surface of the corner upper dummy pad CDP2, which is observable by the measurement device AP which is aligned in the third direction D3. When viewed in the third direction D3, the first width W1 of the exposed area may be defined as an area from a left edge point PT1 of the corner upper dummy pad CDP2 to a right edge point PT2 thereof. The corner upper dummy pad CDP2 described here may be a pad corresponding to the corner lower dummy pad CDP1 which has the major axis in the third direction D3. Pads corresponding to each other may be pads designed to be bonded to each other at a time of hybrid bonding.

According to some implementations, the measurement device AP may be then aligned to face a side surface of the lower chip 10C, which intersects the first direction D1. The measurement device AP may be arranged obliquely toward a side surface of the upper chip 20C, which intersects the first direction D1.

According to some implementations, the measurement device AP may obtain a second width W2 of an exposed area of the corner lower dummy pad CDP1, which is in the third direction D3. The second width W2 may be equal to the width along the major axis of the corner lower dummy pad CDP1. In some implementations, the measurement device AP may measure the width along the major axis of the corner upper dummy pad CDP2, not the second width W2 of the corner lower dummy pad CDP1. Under an assumption that the width along the major axis of the corner lower dummy pad CDP1 and the width along the width along the major axis of the corner upper dummy pad CDP2 are substantially equal, the second width W2 of the corner lower dummy pad CDP1 may be obtained. When the width along the major axis of the corner lower dummy pad CDP1 and the width along the major axis of the corner upper dummy pad CDP2 are different, the measurement device AP may measure the width along the major axis of the corner upper dummy pad CDP2 and then transmit data thereon to the controller 40. The controller 40 may store received data on the second width W2. Alternatively, the controller 40 may store the received width along the major axis of the corner upper dummy pad CDP2 as the data on the second width W2.

According to some implementations, the controller 40 may receive data on the first width W1 and the data on the second width W2 from the measurement device AP. In some implementations, as described with reference to FIG. 6, the measurement device AP may provide a position value for calculating the first width W1 and the second width W2 to the controller 40, and the controller 40 may calculate the first width W1 and the second width W2 based on the position value.

According to some implementations, the controller 40 may obtain, based on the following Equation 1, an angle θ by which the upper chip 20C rotates from the lower chip 10C.

$$θ = {sin}^{- 1} \frac{W 1}{W 2} \qquad [ Equation ]$$

In the above Equation, “θ” may denote the angle θ by which the upper chip 20C rotates from the lower chip 10C. “W1” may be the first width W1. “W2” may be the second width W2.

However, a scheme in which the controller 40 obtains the angle θ is not limited to the above Equation. The angle θ may be obtained in various ways. A method described in the present disclosure is merely one of methods of obtaining the angle θ through the corner lower dummy pad CDP1 and the corner upper dummy pad CDP2.

Also, in some implementations, the measurement device AP may measure the first width W1 after measuring the second width W2 earlier, not measuring the second width W2 after measuring the first width W1.

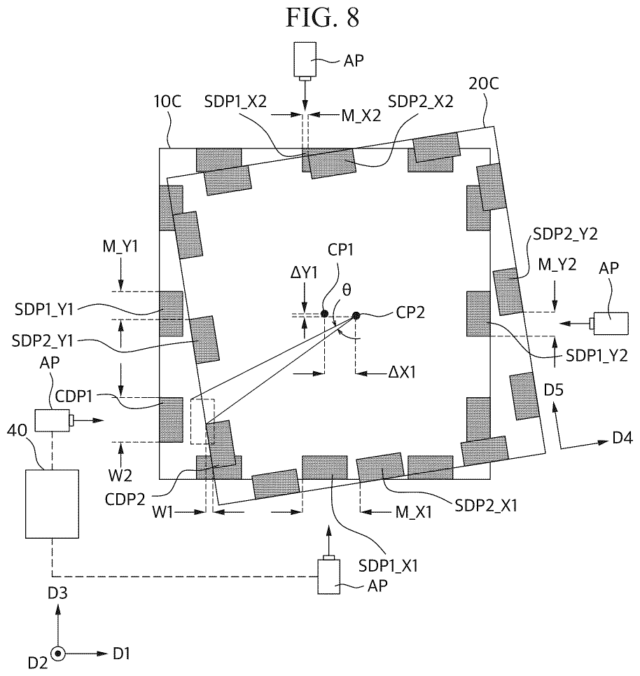

FIG. 8 is a schematic plan diagram for describing a process of obtaining both a misalignment value based on horizontal movement of a stacked semiconductor chip and a misalignment value based on rotational displacement of the stacked semiconductor chip.

FIG. 8 illustrate, in a view intersecting the second direction D2, a case in which while rotating on the lower chip 10C, the upper chip 20C moves in the horizontal direction D1 and/or D3 to be stacked thereon. Thus, the center CP1 of the lower chip 10C and the center CP2 of the upper chip 20C may not overlap in the second direction D2. Thus, the content described above with reference to FIGS. 6 and 7 will be omitted or simplified below.

According to some implementations, in a way identical to the way described above with reference to FIG. 7, an angle θ1 by which the upper chip 20C rotates on the lower chip 10C may be obtained. The angle θ1 may be obtained based on the first width W1 of the corner upper dummy pad CDP2, which is viewed in the third direction D3, and the second width W2 of the corner lower dummy pad CDP1, which is viewed in the first direction D1. Since being described in detail with reference to FIG. 7, description of content thereof will be omitted below.

According to some implementations, a misalignment value based on movement of the upper chip 20C on the lower chip 10C in the horizontal direction D1 and/or D3 may be obtained. The center CP2 of the upper chip 20C may be offset from the center CP1 of the lower chip 10C by the first misalignment value ΔX in the first direction D1. The first misalignment value ΔX may be obtained by using a plurality of side lower dummy pads SDP1_X1 and SDP1_X2 aligned along a surface, which is parallel to the first direction D1, of the lower chip 10C and a plurality of side upper dummy pads SDP2_X1 and SDP2_X2 aligned along a surface, which is parallel to the first direction D1, of the upper chip 20C. The first misalignment value ΔX may be obtained by measuring a distance by which a first side upper dummy pad SDP2_X1 is offset from a first side lower dummy pad SDP1_X1 and a distance by which a second side upper dummy pad SDP2_X2 is offset from a second side lower dummy pad SDP1_X2.

According to some implementations, the first side lower dummy pad SDP1_X1 may be a pad having a surface intersecting a reverse third direction −D3. The first side upper dummy pad SDP2_X1 may be a pad corresponding to the first side lower dummy pad SDP1_X1. In other words, a pad bonded to the first side lower dummy pad SDP1_X1 at a time of hybrid bonding in a misalignment-free situation may be the first side upper dummy pad SDP2_X1.

According to some implementations, the measurement device AP may measure a first position, which is in the first direction D1, of the first side lower dummy pad SDP1_X1 which is exposed at a side surface, which intersects the revers third direction −D3, of the lower chip 10C. The first position may be a position of an outermost edge of the exposed first side lower dummy pad SDP1_X1, which is in the first direction D1. Also, the measurement device AP may measure a second position, which is in the first direction D1, of the first side upper dummy pad SDP2_X1 which is exposed at a side surface, which intersects a reverse fifth direction −D5, of the upper chip 20C. A fifth direction D5 may be a direction rotated, in a horizontal view, a counterclockwise from the third direction D3 by the angle θ1 by which the upper chip 20C rotates. A fourth direction D4 may be a direction rotated, in a horizontal view, a counterclockwise from the first direction D1 by the angle θ1 by which the upper chip 20C rotates. The second position may be a position of an outermost edge of the exposed first side upper dummy pad SDP2_X1, which is in the first direction D1. The first position may be an exposed left edge point of the first side lower dummy pad SDP1_X1, and the second position may be an exposed left edge point of the first side upper dummy pad SDP2_X1. However, the first position and the second position are not necessarily limited to the above description. Positions of points corresponding to each other for position comparison between the first side lower dummy pad SDP1_X1 and the first side upper dummy pad SDP2_X1 may suffice therefor.

According to some implementations, a difference between a first position value and a second position value may be a first offset value M_X1. The controller 40 may receive data on the first offset value M_X1 from the measurement device AP. In some implementations, the measurement device AP may transmit data on the first position value and the second position value to the controller 40. At this point, the controller 40 may obtain the first offset value M_X1 through the difference between the first position value and the second position value.

In the present example, the second side lower dummy pad SDP1_X2 may be a pad having a surface intersecting the reverse third direction −D3. The second side upper dummy pad SDP2_X2 may be a pad corresponding to the second side lower dummy pad SDP1_X2.

According to some implementations, the measurement device AP may measure a third position, which is in the first direction D1, of the second side lower dummy pad SDP1_X2 which is exposed at a side surface, which intersects the third direction D3, of the lower chip 10C. The third position may be a position of an outermost edge of the exposed second side lower dummy pad SDP1_X2, which is in the first direction D1. Also, the measurement device AP may measure a fourth position, which is in the first direction D1, of the second side upper dummy pad SDP2_X2 which is exposed at a side surface, which intersects the fifth direction D5, of the upper chip 20C. The fourth position may be a position of an outermost edge of the exposed second side upper dummy pad SDP2_X2, which is in the first direction D1. The third position may be an exposed right edge point of the first side lower dummy pad SDP1_X2, and the fourth position may be an exposed right edge point of the first side upper dummy pad SDP2_X2. However, the third position and the fourth position are not necessarily limited to the above description. Positions of points corresponding to each other for position comparison between the second side lower dummy pad SDP1_X2 and the second side upper dummy pad SDP2_X2 may suffice therefor.

According to some implementations, a difference between a third position value and a fourth position value may be a second offset value M_X2. The controller 40 may receive data on the second offset value M_X2 from the measurement device AP. In some implementations, the measurement device AP may transmit data on the third position value and the fourth position value to the controller 40. At this point, the controller 40 may obtain the second offset value M_X2 through the difference between the third position value and the fourth position value.

According to some implementations, the controller 40 may obtain a first misalignment value ΔX1 of the upper chip 20C, which is in the first direction D1, through a difference between the first offset value M_X1 and the second offset value M_X2.

According to some implementations, the center CP2 of the upper chip 20C may be offset from the center CP1 of the lower chip 10C by a second misalignment value ΔY1 in the third direction D3. The second misalignment value ΔY1 may be obtained by using a plurality of side lower dummy pads SDP1_Y1 and SDP1_Y2 aligned along a surface, which is parallel to the third direction D3, of the lower chip 10C and a plurality of side upper dummy pads SDP2_Y1 and SDP2_Y2 aligned along a surface, which is parallel to the third direction D3, of the upper chip 20C. The second misalignment value ΔY1 may be obtained by measuring a distance by which a third side upper dummy pad SDP2_Y1 is offset from a third side lower dummy pad SDP1_Y1 and a distance by which a fourth side upper dummy pad SDP2_Y2 is offset from a fourth side lower dummy pad SDP1_Y2.

In the present example, the third side lower dummy pad SDP1_Y1 may be a pad having a surface intersecting a reverse first direction −D1. The third side upper dummy pad SDP2_Y1 may be a pad corresponding to the third side lower dummy pad SDP1_Y1.

According to some implementations, the measurement device AP may measure a fifth position, which is in the first direction D1, of the third side lower dummy pad SDP1_Y1 which is exposed at a side surface, which intersects the revers first direction −D1, of the lower chip 10C. The fifth position may be a position of an outermost edge of the exposed third side lower dummy pad SDP1_Y1, which is in the third direction D3. Also, the measurement device AP may measure a sixth position, which is in the first direction D1, of the third side upper dummy pad SDP2_Y1 which is exposed at a side surface, which intersects a reverse fourth direction −D4, of the upper chip 20C. The sixth position may be a position of an outermost edge of the exposed third side upper dummy pad SDP2_Y1, which is in the third direction D3. The third position may be an exposed right edge point of the third side upper dummy pad SDP2_Y1. However, the fifth position and the sixth position are not necessarily limited to the above description. Positions of points corresponding to each other for position comparison between the third side lower dummy pad SDP1_Y1 and the third side upper dummy pad SDP2_Y1 may suffice therefor.

According to some implementations, a difference between a fifth position value and a sixth position value may be a third offset value M_Y1. The controller 40 may receive data on the third offset value M_Y1 from the measurement device AP. In some implementations, the measurement device AP may transmit data on the fifth position value and the sixth position value to the controller 40. At this point, the controller 40 may obtain the third offset value M_Y1 through the difference between the fifth position value and the sixth position value.

In the present example, the fourth side lower dummy pad SDP1_Y2 may be a pad having a surface intersecting the first direction D1. The fourth side upper dummy pad SDP2_Y2 may be a pad corresponding to the fourth side lower dummy pad SDP1_Y2.

According to some implementations, the measurement device AP may measure a seventh position, which is in the third direction D3, of the fourth side lower dummy pad SDP1_Y2 which is exposed at a side surface, which intersects the first direction D1, of the lower chip 10C. The seventh position may be a position of an outermost edge of the exposed fourth side lower dummy pad SPD1_Y2, which is in the third direction D3. Also, the measurement device AP may measure an eighth position, which is in the third direction D3, of the fourth side upper dummy pad SDP2_Y2 which is exposed at a side surface, which intersects the fourth direction D4, of the upper chip 20C. The eighth position may be a position of an outermost edge of the exposed fourth side upper dummy pad SDP2_Y2, which is in the third direction D3. The eighth position may be an exposed left edge point of the fourth side upper dummy pad SDP2_Y2. However, the seventh position and the eighth position are not necessarily limited to the above description. Positions of points corresponding to each other for position comparison between the third side lower dummy pad SDP1_Y2 and the third side upper dummy pad SDP2_Y2 may suffice therefor.

According to some implementations, a difference between a seventh position value and an eighth position value may be a fourth offset value M_Y2. The controller 40 may receive data on the fourth offset value M_Y2 from the measurement device AP. In some implementations, the measurement device AP may transmit data on the seventh position value and the eighth position value to the controller 40. At this point, the controller 40 may obtain the fourth offset value M_Y2 through the difference between the seventh position value and the eighth position value.

According to some implementations, the controller 40 may obtain the second misalignment value ΔY1 of the upper chip 20C, which is in the third direction D3, through a difference between the third offset value M_Y1 and the fourth offset value M_Y2.

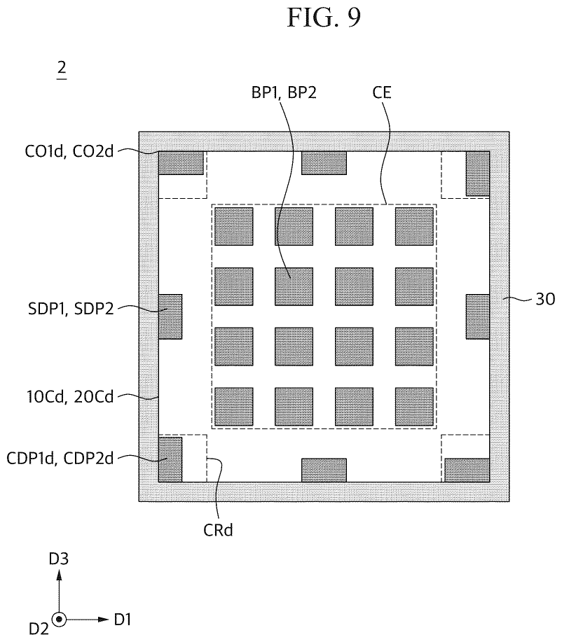

FIG. 9 is a schematic plan diagram for describing a semiconductor device according to another example of the present disclosure.

When compared to the semiconductor device 1 illustrated in FIG. 1, a semiconductor device 2 illustrated in FIG. 9 may be similar or approximately identical thereto, excluding a point that positions and the number of a plurality of corner dummy pads CDP1a and CDP2a disposed in a corner area CRd are different. Thus, a description of the element described above with reference to FIGS. 1 and 2 will be omitted or simplified below.

Referring to FIG. 9, one corner lower dummy pad CDP1a and one corner upper dummy pad CDP2 may be individually disposed to corner areas CRd of a lower chip 10Cd and an upper chip 20Cd. The corner lower dummy pad CDP1d may be disposed to be aligned with a corner CO1d of the lower chip 10Cd. One side surface of the corner lower dummy pad CDP1d may be positioned to be aligned with one side surface of the lower chip 10Cd, and another side surface of the corner lower dummy pad CDP1d, which intersects the one side surface, may be aligned with another side surface of the lower chip 10Cd, which intersects the one side surface. In addition, in a horizontal view intersecting the second direction d2, a corner of the corner lower dummy pad CDP1d may be disposed to correspond to the corner CO1d of the lower chip 10Cd.

The corner upper dummy pad CDP2d may be disposed to be aligned with a corner CO2d of the upper chip 20Cd. One side surface of the corner upper dummy pad CDP2d may be positioned to be aligned with one side surface of the upper chip 20Cd, and another side surface of the corner lower upper pad CDP2d, which intersects the one side surface, may be aligned with another side surface of the upper chip 20Cd, which intersects the one side surface. In addition, in the horizontal view intersecting the second direction d2, a corner of the corner upper dummy pad CDP2d may be disposed to correspond to the corner CO2d of the upper chip 20Cd.

FIG. 10 is a schematic plan diagram for describing a semiconductor device according to another example of the present disclosure.

When compared to the semiconductor device 1 illustrated in FIG. 1, a semiconductor device 3 illustrated in FIG. 10 may be similar or approximately identical thereto, excluding a point that the number of side dummy pads SDP1e and SDP2e disposed between a pair of corner areas CR disposed adjacently around the lower chip 10Ce and the upper chip 20Ce is different. Thus, a description of the element described above with reference to FIGS. 1 and 2 will be omitted or simplified below.

According to some implementations, unlike the semiconductor device 1 illustrated in FIG. 1, at least two or more side dummy pads SDP1e and SDP2e may be disposed between the pair of adjacent corner areas CR in the semiconductor device 3 illustrated in FIG. 10.

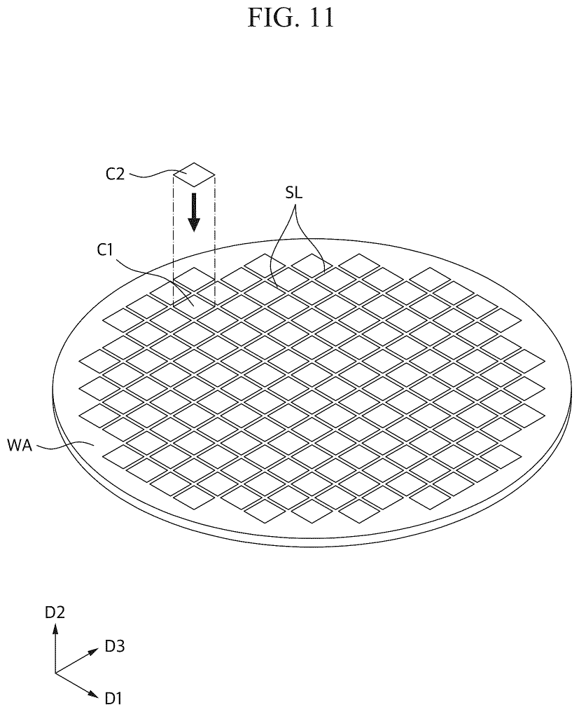

FIG. 11 is a schematic perspective diagram for describing a die-to-wafer bonding scheme.

Referring to FIG. 11, a plurality of first chips C1 is arranged on a wafer WA that is an object of bonding. Each chip may be formed to occupy a predetermined quadrangular area. The wafer WA may be used as a substrate for performing a packaging or bonding process at a wafer level.

According to some implementations, the die-to-wafer bonding scheme may be a scheme of aligning and bonding an individually prepared second chip C2 at a corresponding position on the wafer WA. The second chip C2 may be, for example, a die diced from another wafer and individually prepared. As illustrated, the second chip C2 may be moved in the reverse second direction −D2 from a place higher than the wafer and may be aligned and bonded on a corresponding first chip C1. The above-described bonding may be performed by interposing an adhesive layer or by heat, pressure, a laser, or the like. For example, the bonding may be hybrid bonding.

According to some implementations, as being integrated after the bonding, the first chip C1 and the second chip C2 may be in a state in which a subsequent process (e.g., forming a redistribution layer, molding, forming an external terminal, or the like) is performable therefor. A scribe lane SL may divide the first chips C1 of the wafer WA. The scribe lane SL may be a line for cutting the wafer WA and may serve as a reference line for separating the first chip C1 individually through a subsequent dicing process.

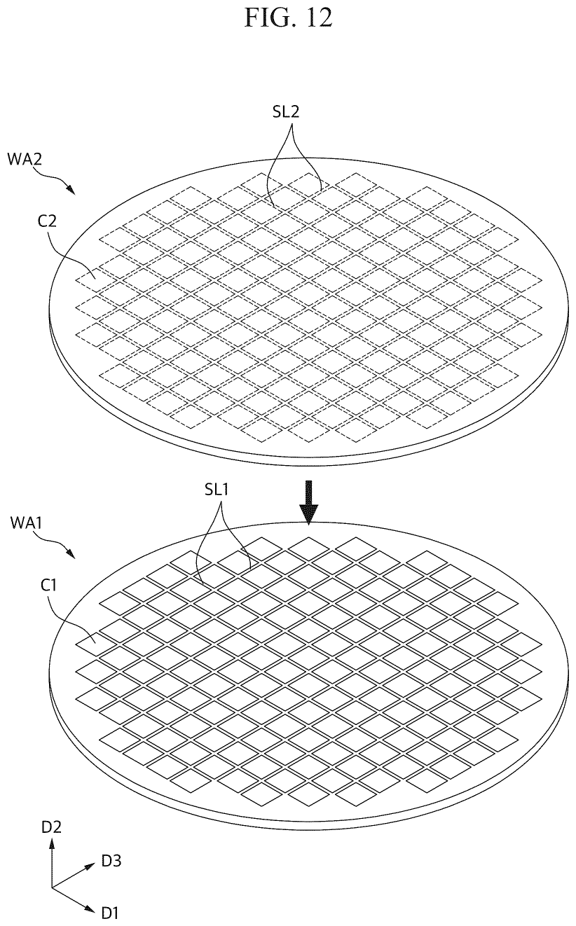

FIG. 12 is a schematic perspective diagram for describing a wafer-to-wafer bonding scheme.

Referring to FIG. 12, the wafer-to-wafer bonding scheme may be a scheme of individually preparing a first wafer WA1 and a second wafer WA2 and then aligning and bonding the above-described wafers together.

According to some implementations, the first wafer WA1 may include the plurality of first chips C1, and each first chip C1 may be disposed in a form of a matrix on the first wafer WA1. A first scribe lane SL1 may be formed between the first chips C1 and serve as a separation reference line for a subsequent dicing process.

According to some implementations, the second wafer WA1 also may include a plurality of second chips C2, and a second scribe line SL2 may be formed between the second chips C2. The second wafer WA2 may be positioned above the first wafer WA1. The first wafer WA1 and the second wafer WA2 may be aligned so that the first chips C1 and the second chips C2 are aligned based on a one-to-one basis before bonding or during bonding.

According to some implementations, afterward, the second wafer WA2 may descend in the reverse second direction −D2, bonding between a first chip C1 and a corresponding second chip C2 may be performed. For example, the bonding may be hybrid bonding.

According to some implementations, after the bonding, a state in which the first wafer WA1 and the second wafer WA2 are integrated may be maintained. Then, a structure in which the first chip C1 and the second chip C2 are integrated may be individually separated through the dicing process. At this point, the first scribe lane SL1 and a second scribe lane SL2 may function as separation reference lines for the first wafer WA1 and the second wafer WA2.

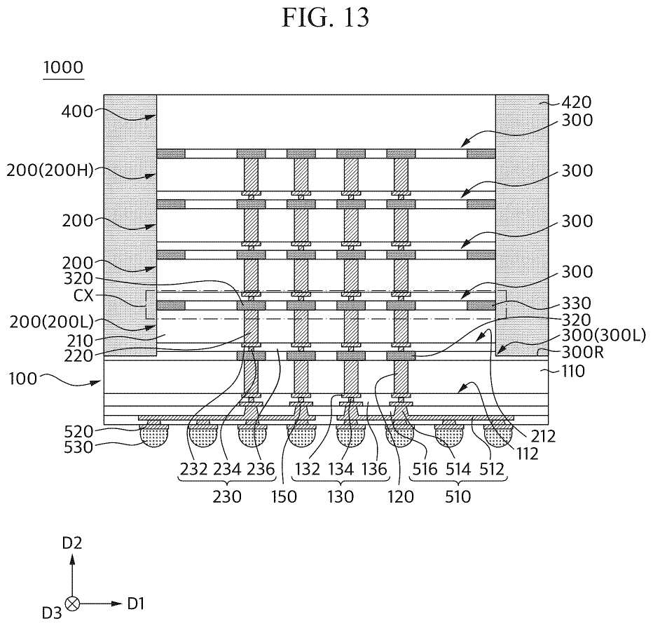

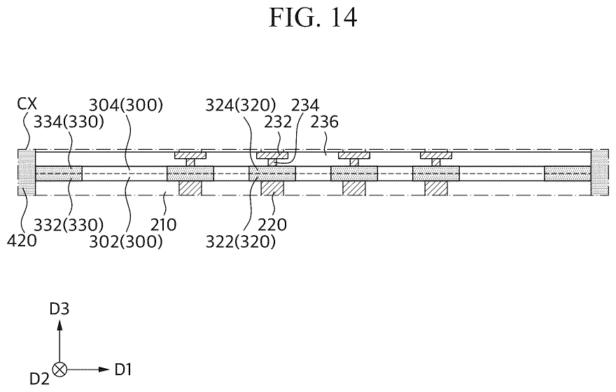

FIG. 13 is a schematic cross-sectional diagram for describing a semiconductor device according to another example of the present disclosure. FIG. 14 is an enlarged diagram illustrating an enlargement of a section marked “CX” of FIG. 13.

A semiconductor device 1000 illustrated in FIGS. 13 and 14 may be a stack-type semiconductor device in which a plurality of chips is stacked in a die-to-wafer bonding scheme illustrated in FIG. 11 or a wafer-to-wafer bonding scheme illustrated in FIG. 12.

Referring to FIGS. 13 and 14, the semiconductor device 1000 may include a first semiconductor chip 100 and a plurality of second semiconductor chips 200. FIG. 13 illustrates that the semiconductor device 1000 includes four second semiconductor chips 200, but is merely an example. For example, the semiconductor device 1000 may include two or more second semiconductor chips 200. In some implementations, the semiconductor device 1000 may include second semiconductor chips 200 of which the number is a multiple of four. The plurality of second semiconductor chips 200 may be sequentially stacked above the first semiconductor chip 100. For convenience for description, among the plurality of second semiconductor chips 200, a lowermost second semiconductor chip 200 may be referred to as a lowermost semiconductor chip 200L, and an uppermost semiconductor chip 200 may be referred to as an uppermost semiconductor chip 200H.

According to some implementations, the first semiconductor chip 100 and the plurality of second semiconductor chips 200 of the semiconductor device 1000 may be electrically connected to each other through a plurality of bonding pads 320 to transmit and receive a signal and provide power and a ground. For example, the plurality of bonding pads 320 may be interposed between the first semiconductor chip 100 and the lowermost second semiconductor chip 200L and between two adjacent second semiconductor chips 200. A bonding pad 320 interposed between the first semiconductor chip 100 and the lowermost second semiconductor chip 200L among the plurality of bonding pads 320 may be referred to as a first bonding pad. A bonding pad 320 interposed between two adjacent second semiconductor chips 200 may be referred to as a second bonding pad.

According to some implementations, the semiconductor device 1000 may include a dummy pad 330 disposed in an outer region in a chip coupling insulation layer 300. The dummy pad 330 will be described in detail below.

According to some implementations, the first semiconductor chip 100 may include a first semiconductor substrate 110 having an active surface and an inactive surface opposite to each other, a first semiconductor device 112 formed on the active surface of the first semiconductor substrate 110, a first wiring structure 130 formed on the active surface of the first semiconductor substrate 110, and a plurality of first through electrodes 120 connected to the first wiring structure 130 and penetrating at least a portion of the first semiconductor chip 100. The first semiconductor chip 100 may be disposed on a lower surface and further include a plurality of chip pads 150 electrically connected to a first wiring pattern 132 and/or a first wiring via 134. The plurality of chip pads 150 may be electrically connected to the first semiconductor device 112 or the first wiring structure 130 through the first wiring pattern 132 and/or the first wiring via 134.

According to some implementations, in the semiconductor device 1000, the first semiconductor chip 100 may be disposed so that the active surface of the first semiconductor substrate 110 faces below and so that the inactive surface thereof faces above.

According to some implementations, a second semiconductor chip 200 may include a second semiconductor substrate 210 having an active surface and an inactive surface opposite to each other, a second semiconductor device 212 formed on the active surface of the second semiconductor substrate 210, and a second wiring structure 230 formed on the active surface of the second semiconductor substrate 210.

According to some implementations, each of the plurality of second semiconductor chips 200 may further include a plurality of second through electrodes 220 connected to the second wiring structure 230 and penetrating at least a portion of the second semiconductor chip 200. Among the plurality of second semiconductor chips 200, even the uppermost second semiconductor chip 200H which is a second semiconductor chip 200 disposed farthest from the first semiconductor chip 100 and positioned at an uppermost end of a semiconductor package 1000 may include the plurality of second through electrodes 220.

According to an example, among the plurality of second semiconductor chips 200, a vertical height of the uppermost second semiconductor chip 200H, namely, a thickness thereof and a vertical height of another second semiconductor chip 200, namely, a thickness thereof may have approximately equal values.

According to an example, materials included in the first semiconductor substrate 110 and the second semiconductor substrate 210 may be substantially identical to materials included the lower substrate 10W (see FIG. 2) and the upper substrate 20W (see FIG. 2) described above with reference to FIG. 2. In addition, structures or individual devices included in the first semiconductor substrate 110 and the second semiconductor substrate 210 may be substantially identical to those of the lower substrate 10W and the upper substrate 20W described above with reference to FIG. 2. Thus, content described above with reference to FIG. 2 will be omitted below.

According to some implementations, at least one of the first semiconductor chip 100 and the second semiconductor chip 200 may be a memory semiconductor chip. In some implementations, the first semiconductor chip 100 may include a serial-parallel conversion circuit and may be a buffer chip for controlling the plurality of second semiconductor chips 200. The plurality of second semiconductor chips 200 may be a memory chip including memory cells. For example, the semiconductor package 1000 including the first semiconductor chip 100 and the plurality of second semiconductor chips 200 may be a high bandwidth memory (HBM). The first semiconductor chip 100 may be referred to as an HBM controller die. Each of the plurality of second semiconductor chips 200 may be referred to as a DRAM die.

According to some implementations, the first wiring structure 130 may be formed with a plurality of first wiring patterns 132, a plurality of first wiring vias 134 connected to the plurality of first wiring patterns 132, and a first inter-wiring insulation layer 136 surrounding the plurality of first wiring pattern 132 and the plurality of first wiring vias 134. In some implementations, the plurality of first wiring patterns 132 may have a thickness less than or equal to approximately 0.5 μm. In some implementations, the first wiring structure 130 may have a multilayered wiring structure including the first wiring pattern 132 and the first wiring via 134 which are disposed at different vertical levels.

According to some implementations, the second wiring structure 230 may be formed with a plurality of second wiring patterns 232, a plurality of second wiring vias 234 connected to the plurality of second wiring patterns 232, and a second inter-wiring insulation layer 236 surrounding the plurality of second wiring patterns 232 and the plurality of second wiring vias 234. In some implementations, the plurality of second wiring patterns 232 may have a thickness less than or equal to approximately 0.5 μm. In some implementations, the second wiring structure 230 may have a multilayered wiring structure including a second wiring pattern 232 and a second wiring via 234 disposed at different vertical levels.

According to some implementations, materials included in the first wiring pattern 132, the first wiring via 134, the second wiring pattern 232, the second wiring via 234, a bonding pad 320, and the dummy pad 330 may be substantially identical to materials included in the lower bonding pad BP1, the lower dummy pad DP1, the upper bonding pad BP2, and the upper dummy pad DP2 described above with referent to FIG. 2. Also, materials included in the first inter-wiring insulation layer 136 and the second inter-wiring insulation layer 236 may be substantially identical to materials included in the lower wiring insulation layer 11, the upper wiring insulation layer 21, and the lower bonding insulation layer BL1, and the upper bonding insulation layer BL2. Thus, content described above with reference to FIG. 2 will be omitted below.

According to some implementations, a first through electrode 120 and a second through electrode 220 each may be formed as a through silicon via (TSV). The first through electrode 120 and the second through electrode 220 each may include a conductive plug that penetrates each of the first semiconductor substrate 110 and the second semiconductor substrate 210 and include a conductive barrier film that surrounds the conductive plug. The conductive plug may have a cylindrical shape, and the conductive barrier film may have a cylindrical shape that surround a side wall of the conductive plug. A via insulation film may be interposed between the first through electrode 120 and the first semiconductor substrate 110 and between the second through electrode 220 and the second semiconductor substrate 210 to surround side walls of the first through electrode 120 and the second through electrode 220. Also, the first through electrode 120 and the second through electrode 220 may be formed in one of a via-first structure, a via-middle structure, and a via-last structure.

According to some implementations, a lowermost chip coupling insulation layer 300L may have a recess 300R at an upper portion thereof so that a thickness of a portion vertically overlapping the lowermost second semiconductor chip 200L has a value larger than that of a portion not overlapping the lowermost second semiconductor chip 200L in the second direction D2. The recess 300R may be positioned at the portion of the lowermost chip coupling insulation layer 300L, which does not overlap the lowermost second semiconductor chip 200L in the second direction D2. The lowermost chip coupling insulation layer 300L may have a shape in which a middle portion, namely, a portion overlapping the lowermost second semiconductor chip 200L in the second direction D2 protrudes above further than an edge portion, namely, the portion not overlapping the lowermost second semiconductor chip 200L in the second direction D2 and may have a flat lower surface.

According to some implementations, a support dummy substrate 400 may be stacked on the uppermost second semiconductor chip 200H. The support dummy substrate 400 may include, for example, a semiconductor material such as silicon (Si). According to some implementations, the support dummy substrate 400 may be formed entirely of the semiconductor material. For example, the support dummy substrate 400 may be a portion of a bare wafer.

According to some examples, the semiconductor device 1000 may further include a base redistribution layer 510 disposed on a lower surface of the first semiconductor chip 100. The base redistribution layer 510 may include a plurality of redistribution line patterns 512, a plurality of redistribution vias 514, and a redistribution insulation layer 516. In some implementations, a plurality of redistribution insulation layers 516 may be stacked. The redistribution insulation layer 516 may be formed of a photo-imageable dielectric (PID) or photosensitive polyimide (PSPI). A redistribution line pattern 512 and a redistribution via 514 may be, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru) or an alloy thereof, but it is merely an example. In some implementations, the redistribution line pattern 512 and the redistribution via 514 may be formed as a metal or a metallic alloy is stacked on a seed layer including titanium, titanium nitride, or titanium tungsten.

According to some implementations, the plurality of redistribution line patterns 512 may be disposed on at least one of an upper surface and a lower surface of the redistribution insulation layer 516. The plurality of redistribution vias 514 may be in contact with and connected to some of the plurality of redistribution line patterns 512 by penetrating the redistribution insulation layer 516. In some implementations, at least some of the plurality of redistribution line patterns 512 may be formed together with some of the plurality of redistribution vias 514 to be integrally formed. For example, the redistribution line pattern 512 and the redistribution via 514 which is in contact with an upper surface of the redistribution line pattern 512 may be integrally formed. The redistribution insulation layer 516 may surround the plurality of redistribution line patterns 512 and the plurality of redistribution vias 514.

According to some implementations, the plurality of redistribution line pattern 512 and the plurality of redistribution via 514 may be electrically connected to the plurality of chip pads 150. In some implementations, some of the plurality of redistribution vias 514 may be in contact with the plurality of chip pads 150. For example, when the base redistribution layer 510 includes the stacked plurality of redistribution insulation layers 516, the redistribution via 514 which penetrates an uppermost redistribution insulation layer 516 may be in contact with and electrically connected to a chip pad 150.

The redistribution line pattern 512 which is disposed on a lower surface of the base redistribution layer 510 among the plurality of redistribution line patterns 512 may be referred to as a redistribution pad 520. A plurality of external connection terminals 530 may be attached to a plurality of redistribution pads 520. For example, an external connection terminal 530 may be a solder ball or bump.

According to some implementations, the plurality of bonding pads 320 may be electrically connected to the plurality of first through electrode 120 or the plurality of second through electrode 220. For example, the second wiring pattern 232 and/or the second wiring via 234 of the second wiring structure 230 which is included in the lowermost second semiconductor chip 200L may be electrically connected to, through the plurality of bonding pads 320, namely, a plurality of first bonding pads, the plurality of first through electrodes 120 included in the first semiconductor chip 100 positioned below. The second wiring pattern 232 and/or the second wiring via 234 of the second wiring structure 230 which is included in the second semiconductor chip 200 other than the lowermost second semiconductor chip 200L may be electrically connected to, through the plurality of bonding pads 320, namely, a plurality of second bonding pads, the plurality of second through electrodes 220 included in another second semiconductor chip 200 positioned below.

According to some implementations, the plurality of bonding pads 320 may be surrounded by the chip coupling insulation layer 300 between the first semiconductor chip 100 and the plurality of second semiconductor chips 200, namely, between the first semiconductor chip 100 and the lowermost second semiconductor chip 200, and between the plurality of second semiconductor chips 200. The plurality of bonding pads 320 may penetrate the chip coupling insulation layer 300. A plurality of chip coupling insulation layers 300 may be interposed individually between the first semiconductor chip 100 and the plurality of second semiconductor chips 200.

FIG. 14 illustrates an enlargement of the chip coupling insulation layer 300 and the plurality of bonding pads 320. Hybrid bonding illustrated in FIG. 14 may be substantially identical to hybrid bonding illustrated in FIG. 2. Bonding of the lower chip 10C (see FIG. 2) and the upper chip 20C (see FIG. 2) illustrated in FIG. 2 may be implemented in bonding of the plurality of second semiconductor chips 200 illustrated in FIG. 14. A second semiconductor chip 200 positioned below in a pair of second semiconductor chips 200 bonded to each other may correspond to the lower chip 10C illustrated in FIG. 2. A semiconductor chip 200 positioned above therein may correspond to the upper chip 20C illustrated in FIG. 2. The second through electrode 220 illustrated in FIG. 14 may correspond to the lower via 12 illustrated in FIG. 2, and the second wiring via 234 illustrated in FIG. 14 may correspond to the upper via 22 illustrated in FIG. 2.

According to some examples, the bonding pad 320 may be formed with an upper surface chip connection pad 322 and a lower surface chip connection pad 324 that face and are bonded to each other in the second direction D2. The chip coupling insulation layer 300 may be formed with an upper surface chip coupling insulation material layer 302 and a lower surface chip coupling insulation material layer 304 that face and are bonded to each other in the second direction D2. The upper surface chip connection pad 322 illustrated in FIG. 14 may correspond to the lower bonding pad BP1 illustrated in FIG. 2, and the lower surface chip connection pad 324 illustrated in FIG. 14 may correspond to the upper bonding pad BP2 illustrated in FIG. 2. The upper surface chip coupling insulation material layer 302 illustrated in FIG. 14 may correspond to the lower bonding insulation layer BL1 illustrated in FIG. 2, and the lower surface chip coupling insulation material layer 304 illustrated in FIG. 14 may correspond to the upper bonding insulation layer BL2 illustrated in FIG. 2.

According to some implementations, the semiconductor device 1000 may include a lower dummy pad 332 having an outer side surface aligned with an outer side surface of the upper surface chip coupling insulation material layer 302 and an upper dummy pad 334 having an outer side surface aligned with an outer side surface of the lower surface chip coupling insulation material layer 304. Outer side surfaces of the lower dummy pad 332 and the upper dummy pad 334, which cross the horizontal direction D1 and/or D3, may be in contact with a molding layer 420. The lower dummy pad 332 may correspond to the side lower dummy pad SDP1 and the corner lower dummy pad CDP1 illustrated in FIG. 2. The upper dummy pad 334 may correspond to the side upper dummy pad SDP2 and the corner upper dummy pad CDP2 illustrated in FIG. 2. The lower dummy pad 332 and the upper dummy pad 334 may be exposed to an outside in a process, in which the plurality of second semiconductor chips 200 is stacked, to show an index for measuring a misalignment value. Since content therefor has been described with reference to FIGS. 1, 2, 6, 7, and 8, a redundant description will be omitted.

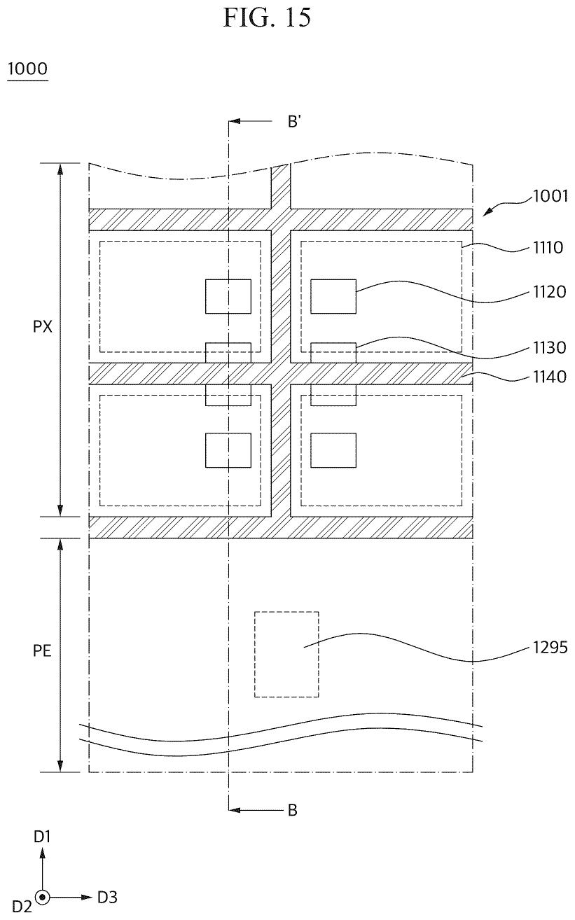

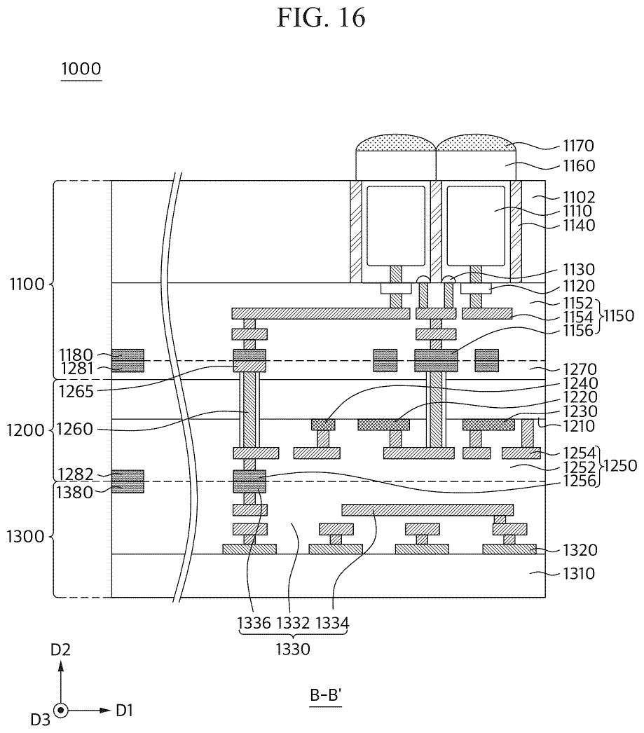

FIG. 15 is a schematic plan diagram for describing a semiconductor device according to another example of the present disclosure. FIG. 16 is an example diagram illustrating a cross section taken along line B-B′ of FIG. 15.

Referring to FIGS. 15 and 16, the semiconductor device of the present example may be a CMOS image sensor (CIS) and include three semiconductor chips 1100, 1200, and 1300. Specifically, the semiconductor device 1000 of the present example may include a first chip 1100 to which pixels are disposed, a second chip 1200 to which transistors that process an electronic signal are disposed, and a third chip 1300 to which logic circuits that process an image signal are disposed. For example, the first chip 1100 may include a pixel array in which the pixels are disposed in a two-dimensional array structure. The second chip 1200 may include an electron signal process unit (ESP) including a source follower gate (SF) 1220, a reset gate (RG) 1230, and a select gate (SEL) 1240. The third chip 1300 may include an image sensor processor (ISP) including an analog-digital converter (ADC) and readout circuitry. In addition, the ISP of the third chip 1300 is not limited to the ADC and the readout circuitry and may further include an analog signal processing circuit, an image signal processing circuit, a control circuit, or the like. In some implementations, the ADC may be disposed to the second chip 1200. The semiconductor device 1000 of the present example may implement high definition by maximizing the number of pixels in the first chip 1100 and optimize signal processing through the second chip 1200 and the third chip 1300.

According to some implementations, the semiconductor device 1000 may be a stack-type semiconductor device in which the first chip 1100, the second chip 1200, and the third chip 1300 are stacked in a die-to-wafer bonding scheme illustrated in FIG. 11 or a wafer-to-wafer bonding scheme illustrated in FIG. 12.

According to some implementations, the semiconductor device 1000 may include a pixel area PX and a peripheral area PE. The pixel area PX may be an area in which the pixels are disposed, and the peripheral area PE may be an area in which connection wirings for sending an electrical signal in the second direction D2 and an input/output pad 1295 that exchanges the electrical signal with an outside are disposed. In some implementations, the peripheral area PE may surround the pixel area PX. However, structures of the peripheral area PE and the pixel area PX are not limited thereto. For example, the peripheral area PE may not be disposed on at least one side surface among four side surfaces of the pixel area PX.

As described above, the semiconductor device 1000 may include first to third chips 1100, 1200, and 1300 stacked in sequential order in the second direction D2. The first chip 1100 may include a first substrate 1102, the second chip 1200 may include a second substrate 1210, and the third chip 1300 may include a third substrate 1310. Since descriptions of first to third substrates 1102, 1210, 1310 are redundant as being similar to the above descriptions of the lower substrate 10W and the upper substrate 20W with reference to FIGS. 1 and 2, a detailed description will be omitted below.

According to some implementations, in the semiconductor device 1000, devices that convert incident light into an electronic signal may be disposed on the first substrate 1102. Devices that convert the converted electronic signal into a voltage signal may be disposed on the second substrate 1210. Logic circuits that process an electrical signal such as the electronic signal or the voltage signal may be disposed on the third substrate 1310.

According to some implementations, in the first chip 1100, in the second direction D2, the first substrate 1102 may be disposed above, and a first wiring layer 1150 may be disposed below. In addition, a photo-diode (PD) 1100 and a photodiode (PD) isolation pattern 1140 may be disposed in the first substrate 1102. Also, a transfer gate (TG) 1120 having a vertical gate structure in contact with the PD 1110 may be disposed on a lower surface of the first substrate 1102, and a floating diffusion (FD) area 1130 may be disposed to be adjacent to the TG 1120.

According to some implementations, the PD isolation pattern 1140 may isolate the pixels or PDs 1100 in a form of a rectangular grid. For reference, the PD 1110 and a pixel may be similar to each other for horizontal shapes thereof, but the pixel may be a concept further including the TG 1120, the FD area 1130, or the like in addition to the PD 1110.

According to some implementations, TGs 1120 may be disposed to the pixels or the PDs 1110 on a one-to-one basis. The FD area 1130 may be adjacent to the TG 1120 to be disposed to a lower portion of the first substrate 1102. The FD area 1130 may form a source/drain area of the TG 1120.

According to some implementations, the wiring layer 1150 may include a first inter-layer insulation layer 1152, a first wiring 1154, and a first pad 1156. The first wiring 1154 may include a horizontal wiring and a vertical via. When horizontal wirings are disposed in a multilayer, the horizontal wirings in different layers may be connected to each other through the vertical via. An uppermost horizontal wiring among the horizontal wirings may be connected to the TG 1120 and the FD area 1130 through the vertical via.

According to some implementations, a flattened layer may be disposed on an upper surface of the first substrate 1102. Also, on a flattened layer of the pixel area PX, a color filter 1160 and a micro lens 1170 may be disposed to correspond to each of the pixels. A light-blocking metallic layer, an upper flattened layer, or the like may be disposed on a flattened layer of the peripheral area PE.

According to some implementations, color filters 1160 may include a green filter, a blue filter, and a red filter. However, a combination of the color filters 1160 is not limited thereto. Meanwhile, a grid-shaped interference prevention structure may be disposed between the color filters 1160. The interference prevention structure may include, for example, a metal or a low-refraction material.

According to some implementations, the micro lens 1170 and the upper flattened layer may include, for example, a high-transmissivity material. Meanwhile, a transparent protective film formed of SiO, SiOC, SiC, SiCN, or the like may be disposed on the micro lens 1170 and the upper flattened layer.

According to some implementations, in the second chip 1200, in the second direction D2, the second substrate 1210 may be disposed above, and a second wiring layer 1250 may be disposed below. In addition, an upper insulation layer 1270 may be disposed above the second substrate 1210. In the pixel area PX, the SF 1220, the RG 1230, and the SEL 1240 may be disposed on a lower surface of the second substrate 1210. The SF 1220, the RG 1230, and the SEL 1240 may form a source follower transistor, a reset transistor, and a select transistor together with active areas of the second substrate 1210.

According to some implementations, the wiring layer 1250 may include a second inter-layer insulation layer 1252, a second wiring 1254, and a second pad 1256. The second wiring 1254 may include a horizontal wiring and a vertical via. Also, the horizontal wiring may be connected to the SF 1120, RG 1230, and the SEL 1240 through the vertical via.

According to some implementations, the input/output pad 1295 may be disposed in the second wiring layer 1250 of the peripheral area PE. The input/output pad 1295 may be connected to the horizontal wiring of the second wiring 1254 directly or through the vertical via. In some examples, the input/output pad 1295 may be included as a portion of the second wiring 1254.

According to some implementations, the upper insulation layer 1270 may be disposed above the second substrate 1210. The upper insulation layer 1270 may be formed as a multilayer. An upper pad 1265 may be disposed on an upper surface of the upper insulation layer 1270. As described below, the upper pad 1265 may be metal-metal-bonded to the first pad 1156 of the first chip 1100.

According to some implementations, a through electrode 1260 that is in contact with the upper pad 1265 and the second wiring 1254 by penetrating an upper portion of the second inter-layer insulation layer 1252, the second substrate 1210, and the upper insulation layer 1270 may be disposed. The through electrode 1260 may be insulated from the second substrate 1210 by a side wall insulation layer. The through electrode 1260 may be disposed in both the pixel area PX and the peripheral area PE. Meanwhile, since the through electrode 1260 penetrates the second substrate 1210 of Si, the through electrode 1260 may be a TSV.

Hybrid bonding of the first chip 1100 and the second chip 1200 and hybrid bonding of the second chip 1200 and the third chip 1300 illustrated in FIG. 16 may be substantially identical to hybrid bonding illustrated in FIG. 2. Bonding of the lower chip 10C (see FIG. 2) and the upper chip 20C (see FIG. 2) illustrated in FIG. 2 may be implemented in bonding of the first chip 1100 and the second chip 1200 and bonding of the second chip 1200 and the third chip 1300 illustrated in FIG. 16. In a relationship between the first chip 1100 and the second chip 1200, the first chip 1100 may correspond to the upper chip 20C illustrated in FIG. 2, and the second chip 1200 may correspond to the lower chip 10C illustrated in FIG. 2. In a relationship between the second chip 1200 and the third chip 1300, the second chip 1200 may correspond to the upper chip 20C illustrated in FIG. 2, and the third chip 1300 may correspond to the lower chip 10C illustrated in FIG. 2.

According to some implementations, in the relationship between the first chip 1100 and the second chip 1200, the first pad 1156 may correspond to the upper bonding pad BP2 (see FIG. 2) illustrated in FIG. 2, and the upper pad 1265 may correspond to the lower bonding pad BP1 (see FIG. 2) illustrated in FIG. 2. The first inter-layer insulation layer 1152 may correspond to the upper bonding insulation layer BL2 (see FIG. 2) illustrated in FIG. 2, and the upper insulation layer 1270 may correspond to the lower bonding insulation layer BL1 (see FIG. 2) illustrated in FIG. 2.

According to some implementations, in the relationship between the second chip 1200 and the third chip 1300, the second pad 1256 may correspond to the upper bonding pad BP2 illustrated in FIG. 2, and a third pad 1336 may correspond to the lower bonding pad BP1 illustrated in FIG. 2. The second inter-layer insulation layer 1252 may correspond to the upper bonding insulation layer BL2 illustrated in FIG. 2, and a third inter-layer insulation layer 1332 may correspond to the lower bonding insulation layer BL1 illustrated in FIG. 2.

According to some implementations, the first chip 1100 may include a first upper dummy pad 1180 having an outer side surface aligned with an outer side surface of the first inter-layer insulation layer 1152. The second chip 1200 may include a first lower dummy pad 1281 having an outer side surface aligned with an outer side surface of the upper insulation layer 1270. Also, the second chip 1200 may include a second upper dummy pad 1282 having an outer side surface aligned with an outer side surface of the second inter-layer insulation layer 1252. The third chip 1300 may include a second lower dummy pad 1380 having an outer side surface aligned with an outer side surface of the third inter-layer insulation layer 1332.

According to some implementations, outer side surfaces of the first lower dummy pad 1281, the first upper dummy pad 1180, the second lower dummy pad 1380, and the second upper dummy pad 1282, which intersect the horizontal direction D1 and/or D3, may be in contact with a molding layer surrounding the first to third chips 1100, 1200, 1300. The first lower dummy pad 1281 and the second lower dummy pad 1380 may correspond to the side lower dummy pad SDP1 (see FIG. 2) and the corner lower dummy pad CDP1 (see FIG. 2) illustrated in FIG. 2. The first upper dummy pad 1180 and the second upper dummy pad 1282 may correspond to the side upper dummy pad SDP2 (see FIG. 2) and the corner upper dummy pad CDP2 (see FIG. 2) illustrated in FIG. 2. The first lower dummy pad 1281 and the first upper dummy pad 1180 may be exposed to an outside in a process, in which the first chip 1100 and the second chip 1200 are stacked, to show an index for measuring a misalignment value. The second lower dummy pad 1380 and the second upper dummy pad 1282 may be exposed to an outside in a process, in which the plurality of second semiconductor chips 1300 is stacked, to show an index for measuring a misalignment value. Since content therefor has been described with reference to FIGS. 1, 2, 6, 7, and 8, a redundant description will be omitted.

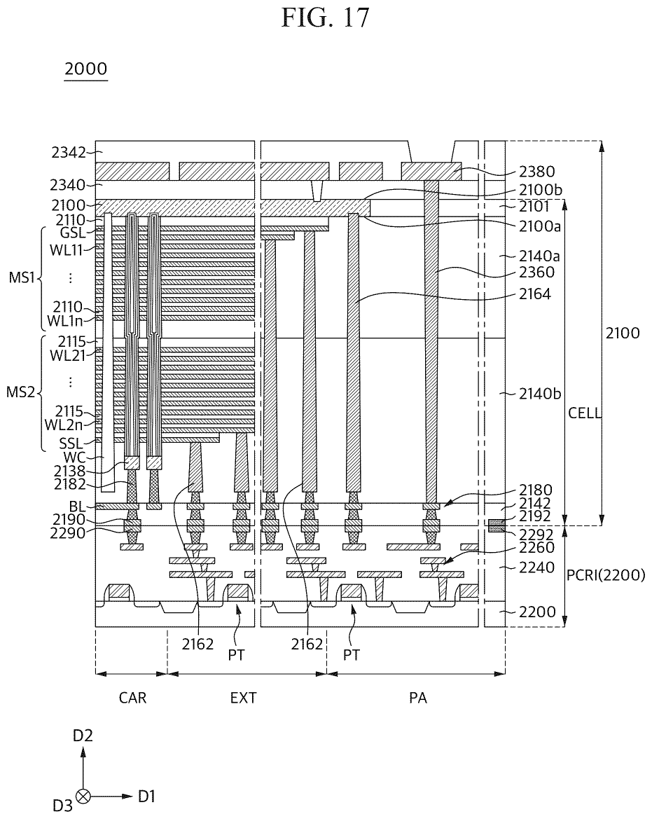

FIG. 17 is a schematic cross-sectional diagram for describing a semiconductor device according to another example of the present disclosure.

A semiconductor device 2000 illustrated in FIG. 17 may be a memory device including a memory cell disposed three-dimensionally. The semiconductor device 2000 may include a cell structure CELL and a peripheral circuit structure PCRI.

According to some implementations, the semiconductor device 2000 may be a stack-type semiconductor device in which a first chip 2100 and a second chip 2200 are stacked in a die-to-wafer bonding scheme illustrated in FIG. 11 or a wafer-to-wafer bonding scheme illustrated in FIG. 12.

According to some implementations, the cell structure CELL may include a cell substrate 2100, an insulation substrate 2101, mold structures MS1 and MS2, inter-layer insulation films 2140a and 2140b, a channel structure CH, a word line cut area WC, a bit line BL, a gate contact 2162, and a cell wiring structure 2180. In some implementations, the cell substrate 2100 may include an impurity. For example, the cell substrate 2100 may include an N-type impurity (e.g., phosphorus (P), arsenic (As), or the like).

According to some implementations, the cell substrate 2100 may include a cell array area CAR and an extended area EXT. A memory cell array including a plurality of memory cells may be formed in the cell array area CAR. For example, the channel structure CH, gate electrodes GSL, WL11 to WL1n, WL21 to WL2n, and SSL, the bit line BL, or the like may be disposed in the cell array area CAR.

According to some implementations, the extended region EXT may be defined near the cell array region CAR. For example, the extended area EXT may surround the cell array area CAR when viewed in a plan view. The gate electrodes GSL, WL11 to WL1n, WL21 to WL2n, and SSL may be stacked in a stepped form in the extended area EXT.

According to some implementations, the insulation substrate 2101 may be formed near the cell substrate 2100. The insulation substrate 2101 may form an insulation area near the cell substrate 2100.

According to some implementations, the cell substrate 2100 and/or the insulation substrate 2101 may further include an outer area PA. The outer area PA may be defined at an outside of the extended area EXT. For example, the outer area PA may surround the extended area EXT when viewed in a plan view intersecting the second direction D2. A contact plug 2360 to be described below may be disposed in the outer area PA.

According to some implementations, the mold structures MS1 and MS2 may be formed on a first surface 2100a of the cell substrate 2100. The mold structures MS1 and MS2 may include a plurality of gate electrodes GSL, WL11 to WL1n, WL21 to WL2n, and SSL stacked on the cell substrate 2100 and include a plurality of mold insulation films 2110 and 2115. Each of the gate electrodes GSL, WL11 to WL1n, WL21 to WL2n, and SSL and each of the mold insulation films 2110 and 2115 may have a layer-shaped structure extended in parallel with the first surface 2100a of the cell substrate 2100. The gate electrodes GSL, WL11 to WL1n, WL21 to WL2n, and SSL may be spaced apart from each other by the mold insulation films 2110 and 2115 and stacked on the cell substrate 2100 in sequential order.

According to some implementations, a first mold stack MS1 may include first gate electrodes GSL and WL11 to WL1n and first mold insulation films 2110 that are alternately stacked on the cell substrate 2100. In some implementations, the first gate electrodes GSL and WL11 to WL1n may include a ground selection line GSL and a plurality of first word lines WL11 to WL1n that are stacked in sequential order on the cell substrate 2100. The number, disposition, or the like of the ground selection line GSL and the first word lines WL11 to WL1n is merely an example and not limited to an illustration.

According to some implementations, a second mold stack MS2 may include second gate electrodes WL21 to WL2n and SSL and second mold insulation films 115 that are alternately stacked below the first mold stack MS1. In some implementations, the second gate electrodes WL21 to WL2n and SSL may include a plurality of second word lines WL21 to WL2n and a string selection line SSL that are stacked in sequential order below the first mold stack MS1. The number, disposition, or the like of the second word lines WL21 to WL2n and the string selection line SSL is merely an example and not limited to an illustration.

According to some implementations, each of the gate electrodes GSL, WL11 to WL1n, WL21 to WL2n, and SSL may include a conductive material. Each of the mold insulation films 2110 and 2115 may include an insulation material.

According to some implementations, the inter-layer insulation films 2140a and 2140b may be formed on the first surface 2100a of the cell substrate 2100 and cover the mold structures MS1 and MS2. In some implementations, the inter-layer insulation films 2140a and 2140b may include a first inter-layer insulation film 2140a and a second inter-layer insulation film 2140b that are stacked on the cell substrate 2100 in sequential order. The first inter-layer insulation film 2140a may cover the first mold stack MS1, and the second inter-layer insulation film 2140b may cover the second mold stack MS2.

According to some implementations, the channel structure CH may be formed in the cell array area CAR of the cell substrate 2100. The channel structure CH may be extended in the second direction D2, which intersects the first surface 2100a of the cell substrate 2100, to penetrate the mold structures MS1 and MS2. For example, the channel structure CH may have a pillar shape (e.g., a cylindrical shape) extended in the second direction D2. Accordingly, the channel structure CH may cross each of the plurality of gate electrodes GSL, WL11 to WL11, WL21 to WL1n, and SSL.

According to some implementations, the word line cut area WC may be extended in the third direction D3 to cut the mold structures MS1 and MS2. The mold structures MS1 and MS2 may be divided by word line cut areas WC to form a plurality of memory cell blocks. The word line cut area WC may include an insulation material (e.g., at least one of silicon oxide, silicon nitride, and silicon oxynitride), but it is merely an example.

According to some implementations, the bit line BL may be formed below the mold structures MS1 and MS2. In addition, the bit line BL may be extended along the third direction D3 to be connected to a plurality of channel structures CH arranged in the third direction D3. For example, a bit line contact 2182 connected to a channel pad 2138 may be formed in the second inter-layer insulation film 2140b. The bit line BL may be electrically connected to the channel structures CH through the bit line contact 2182.

According to some implementations, the gate contact 2162 may be connected to each of the gate electrodes GSL, WL11 to WL1n, WL21 to WL2n, and SSL. For example, each of a plurality of gate contacts 2162 may be extended in the second direction D2 to penetrate the inter-layer insulation films 2140a and 2140b and be connected to corresponding gate electrodes GSL, WL11 to WL1n, WL21 to WL2n, and SSL.

According to some implementations, the cell wiring structure 2180 may be formed below the mold structures MS1 and MS2. For example, a first inter-wiring insulation film 2142 may be formed on the second inter-layer insulation film 2140b, and the cell wiring structure 2180 may be formed in the first inter-wiring insulation film 2142. The cell wiring line 2180 may be electrically connected to bit lines BL and the gate contacts 2162. Through this, the cell wiring structure 2180 may be electrically connected to the channel structure CH and the gate electrodes GSL, WL11 to WL1n, WL21 to WL2n, and SSL.

According to some implementations, a first source contact 2164 connecting the cell substrate 2100 and the cell wiring structure 2180 may be formed. The first source contact 2164 may be, for example, extended in the second direction D2 to penetrate the inter-layer insulation films 2140a and 2140b and electrically connect the cell substrate 2100 and the cell wiring structure 2180.

According to some implementations, the peripheral circuit structure PCRI may include a peripheral circuit substrate 2200, a peripheral circuit device PT, and a peripheral circuit wiring structure 2260.

According to some implementations, the peripheral circuit device PT may be formed on the peripheral circuit substrate 2200. The peripheral circuit device PT may form a peripheral circuit that controls an operation of a semiconductor memory device. For example, the peripheral circuit device PT may include a control logic, a row recorder, a page buffer, or the like.

According to some implementations, the peripheral circuit wiring structure 2260 may be formed on the peripheral circuit device PT. For example, a second inter-wiring insulation film 2240 may be formed on an upper surface of the peripheral circuit substrate 2200, and the peripheral circuit wiring structure 2260 may be formed in the second inter-wiring insulation film 2240. The cell wiring structure 2260 may be electrically connected to the peripheral circuit device PT.

According to some implementations, the cell structure CELL may be stacked on the peripheral circuit structure PCRI. For example, the cell structure CELL may be stacked on the second inter-wiring insulation film 2240.

According to some implementations, as a first bonding pad 2190 of the first chip 2100 and a second bonding pad 2290 of the second chip 2200 are bonded, the cell wiring structure 2180 may be connected to the peripheral circuit wiring structure 2260. Through this, the bit line BL and/or each gate electrode ECL, GSL, WL11 to WL1n, WL21 to WL2n, or SSL may be electrically connected to the peripheral circuit device PT.

According to some implementations, an input/output wiring structure 2380 may be formed above a second surface 2100b of the cell substrate 2100. For example, a third inter-layer insulation film 2340 covering the cell substrate 2100 and the insulation substrate 2101 may be formed on the second surface 2100b of the cell substrate 2100. The input/output wiring structure 2380 may be formed on the third inter-layer insulation film 2340.

According to some implementations, a second source contact 2315 connecting the cell substrate 2100 and the input/output wiring structure 2380 may be formed. The second source contact 2315 may be, for example, extended in the second direction D2 to penetrate the third inter-layer insulation film 2340 and electrically connect the cell substrate 2100 and the input/output wiring structure 2380.

According to some implementations, the contact plug 2360 which connects the cell wiring structure 2180 and the input/output wiring structure 2380 may be formed. The contact plug 2360 may be formed in the outer area PA. The contact plug 2360 may be, for example, extended in the second direction D2 to penetrate the third inter-layer insulation film 2340, the insulation substrate 2101, the first inter-layer insulation film 2140a, and the second inter-layer insulation film 2140b.

According to some implementations, a capping insulation film 2342 covering the input/output wiring structure 2380 may be formed. The capping insulation film 2342 may include, for example, a pad opening OP exposing a portion of the input/output wiring structure 2380. The portion of the input/output wiring structure 2380, which is exposed by the pad opening OP, may be provided as an input/output pad I/O pad.

Hybrid bonding of the first chip 2100 and the second chip 2200 illustrated in FIG. 17 may be substantially identical to hybrid bonding illustrated in FIG. 2. Bonding of the lower chip 10C and the upper chip 20C illustrated in FIG. 2 may be implemented in bonding of the first chip 2100 and the second chip 2200 illustrated in FIG. 17. In a relationship between the first chip 2100 and the second chip 2200, the first chip 2100 may correspond to the upper chip 20C illustrated in FIG. 2, and the second chip 2200 may correspond to the lower chip 10C illustrated in FIG. 2. However, in some implementations, the first chip 2100 may correspond to the lower chip 10C, and the second chip 2200 may correspond to the upper chip 20C. Hereinafter, description will continue from a viewpoint that the first chip 2100 corresponds to the upper chip 20C and that the second chip 2200 corresponds to the lower chip 10C.

According to some implementations, in the relationship between the first chip 2100 and the second chip 2200, the first bonding pad 2190 may correspond to the upper bonding pad BP2 illustrated in FIG. 2, and the second bonding pad 2290 may correspond to the lower bonding pad BP1 illustrated in FIG. 2. The first inter-wiring insulation film 2142 may correspond to the upper bonding insulation layer BL2 illustrated in FIG. 2, and the second inter-wiring insulation film 2240 may correspond to the lower bonding insulation layer BL1 illustrated in FIG. 2.

According to some implementations, the first chip 2100 may include a first dummy pad 2192 having an outer side surface aligned with an outer side surface of the first inter-wiring insulation film 2142. The second chip 2200 may include a second dummy pad 2292 having an outer side surface aligned with an outer side surface of the second inter-wiring insulation film 2240.

According to some implementations, outer side surfaces of the first dummy pad 2192 and the second dummy pad 2292, which intersect the horizontal direction D1 and/or D3, may be in contact with a molding layer surrounding the first chip 2100 and the second chip 2200. The second dummy pad 2292 may correspond to the side lower dummy pad SDP1 and the corner lower dummy pad CDP1 illustrated in FIG. 2. The second dummy pad 2192 may correspond to the side upper dummy pad SDP2 and the corner upper dummy pad CDP2 illustrated in FIG. 2. The first dummy pad 2192 and the second dummy pad 2292 may be exposed to an outside in a process, in which the first chip 2100 and the second chip 2200 are stacked, to show an index for measuring a misalignment value. Since content therefor has been described with reference to FIGS. 1, 2, 6, 7, and 8, a redundant description will be omitted.

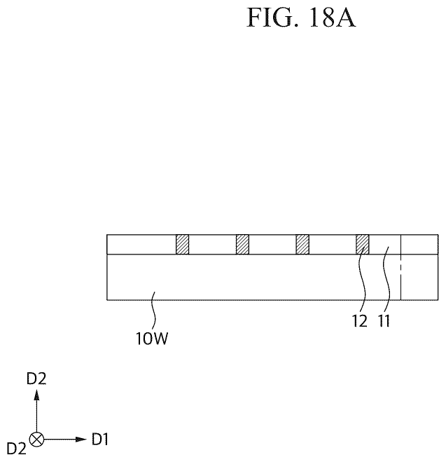

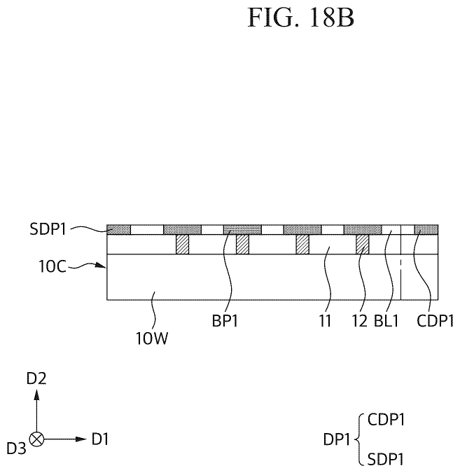

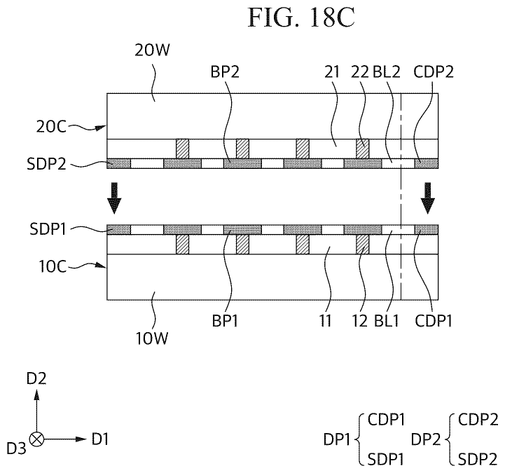

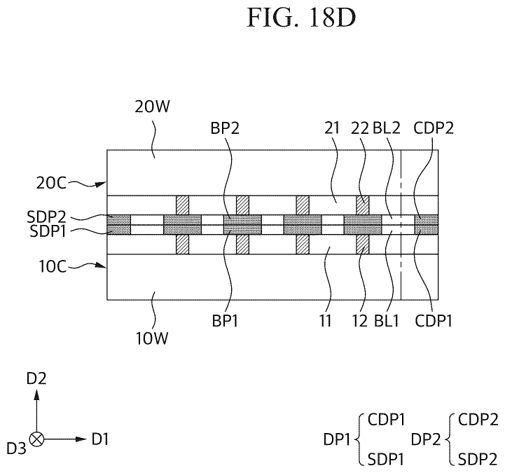

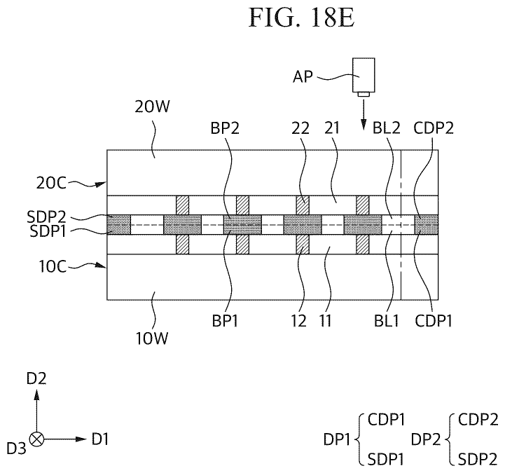

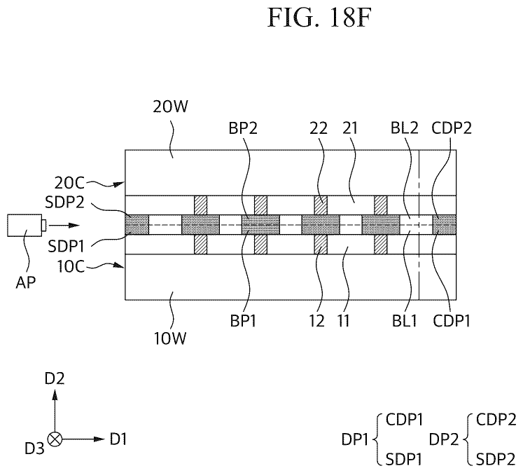

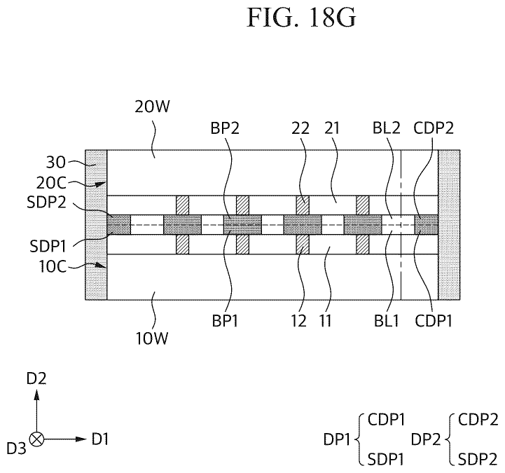

FIGS. 18A through 18G are cross-sectional diagrams sequentially illustrating processes for manufacturing a semiconductor device according to some implementations of the present disclosure. The cross-sectional diagrams of FIGS. 18A through 18G may correspond to a cross-sectional diagram taken along line A-A′ of FIG. 1.

Referring to FIG. 18A, to begin with, the lower substrate 10W with the lower wiring insulation layer 11 and the lower via 12 formed on a back surface thereof may be provided. The lower via 12 may be a portion of a wiring electrically connected to individual devices formed in the lower substrate 10W. The lower wiring insulation layer 11 may be disposed to cover the lower via 12. A back surface of the lower via 12 may be exposed to the lower wiring insulation layer 11.

Referring to FIG. 18b, the plurality of lower bonding pads BP1 and the plurality of lower dummy pads DP1 may be formed on the lower wiring insulation layer 11, so that the lower chip 10C may be completed. Each of the plurality of lower bonding pads BP1 may be formed to be connected to the lower via 12. Each of lower surfaces of the plurality of lower bonding pads BP1 may be connected to an upper surface of the lower via 12. Each of the plurality of lower dummy pads DP1 may be formed not to be connected to the lower via 12. Outer side surfaces of the plurality of lower dummy pads DP1 may be aligned with an outer side surface of the lower wiring insulation layer 11. Unlike the plurality of lower bonding pads BP1, the outer side surfaces of the plurality of lower dummy pads DP1 may be exposed to an outside.

According to some implementations, the lower bonding insulation layer BL1 which surrounds the plurality of lower bonding pads BP1 and the plurality of lower dummy pads DP1 may be formed. The lower bonding insulation layer BL1 may be formed so that upper surfaces of the plurality of lower bonding pads BP1 and upper surfaces of the plurality of lower dummy pads DP1 are exposed. In some implementations, after the plurality of lower bonding pads BP1 and the plurality of lower dummy pads DP1 are formed earlier, the lower bonding insulation layer BL1 which surrounds the plurality of lower bonding pads BP1 and the plurality of lower dummy pads DP1 may be formed. In some implementations, after the lower bonding insulation layer BL1 is formed earlier, the lower bonding insulation layer BL1 may be etched and filled with a conductive material, so that the lower bonding pad BP1 and the plurality of lower dummy pads DP1 may be formed.

Referring to FIGS. 18C and 18D, the upper chip 20C may be attached to the lower chip 10C. Similarly to the lower chip 10C, the upper chip 20C may include the upper substrate 20W, the upper wiring insulation layer 21, the upper via 22, the upper bonding insulation layer BL2, the plurality of upper bonding pads BP2, and the plurality of upper dummy pads DP2.

According to some implementations, the upper chip 20C may be aligned on the lower chip 10C so that the lower bonding pad BP1 and the upper bonding pad BP2 overlap in the second direction D2. As the upper chip 20C is seated on the lower chip 10C, the upper bonding pad BP2 may be in contact with the lower bonding pad BP1. The upper dummy pad DP2 may be in contact with the lower dummy pad DP1. The upper bonding insulation layer BL2 may be in contact with the lower bonding insulation layer BL1 in which the lower bonding pad BP1 or the lower dummy pad DP1 is not exposed.

In some implementations, when the upper bonding pad BP2 is offset from the lower bonding pad BP1 in the horizontal direction D1 and/or D3, a portion of the upper bonding pad BP2 may be in contact with a portion of the lower bonding insulation layer BL1.

According to some implementations, heat and/or pressure may be applied between the lower bonding pad BP1 and the upper bonding pad BP2 and between the lower dummy pad DP1 and the upper dummy pad DP2, so that the lower bonding pad BP1 and the upper bonding pad BP2 may be bonded, and so that the lower dummy pad DP1 and the upper dummy pad DP2 may be bonded. Heat and/or pressure may be applied also between the lower bonding insulation layer BL1 and the upper bonding insulation layer BL2, so that the lower bonding insulation layer BL1 and the upper bonding insulation layer BL2 may be bonded. In some implementations, while forming a covalent bond, the lower bonding pad BP1 and the upper bonding pad BP2 may be bonded to the lower dummy pad DP1 and the upper dummy pad DP2, respectively. The lower bonding insulation layer BL1 and the upper bonding insulation layer BL2 may be bonded together while forming a covalent bond. For example, in a process of positioning the upper chip 20C on the lower chip 10C, heat of a first temperature may be applied.

Referring to FIG. 18E, heat of a second temperature higher than the first temperature may be applied, so that the lower bonding pad BP1 and the upper bonding pad BP2 which correspond to each other may be coupled to each other. The lower dummy pad DP1 and the upper dummy pad DP2 also may be coupled to each other by the heat of the second temperature. The lower bonding insulation layer BL1 and the upper bonding insulation layer BL2 also may be bonded together by the heat of the second temperature. The lower bonding pad BP1 and the upper bonding pad BP2 which correspond to each other may be expanded and bonded together by heat and then may be diffusion-bonded to be integrated through diffusion of included metallic atoms. Similarly, the lower dummy pad DP1 and the upper dummy pad DP2 also may be coupled to each other through diffusion of metallic atoms.

Afterward, Positions of the lower dummy pad DP1 and the upper dummy pad DP2 may be identified by using the measurement device AP. The positions of the lower dummy pad DP1 and the upper dummy pad DP2 may be indirectly identified based on a structure or patten disposed on the upper substrate 20W. However, a method of identifying the positions of the lower dummy pad DP and the upper dummy pad DP is not limited thereto.

Referring to FIG. 18F, a misalignment value generated in a process in which the upper chip 20C is stacked on the lower chip 10C may be measured by using the measurement device AP. Since a process of obtaining the misalignment value by using the measurement device has been described in detail with reference to FIGS. 5 through 7, a detailed description thereof will be omitted below.

Referring to FIG. 18G, afterward, the molding layer 30 which surrounds the lower chip 10C and the upper chip 20C may be formed. The molding layer 30 may be in contact with an outer side surface of the side lower dummy pad SDP1, which intersects the horizontal direction D1 and/or D3, and an outer side surface of the side upper dummy pad SDP2, which intersects the horizontal direction D1 and/or D3. The molding layer 30 may be in contact with an outer side surface of the corner lower dummy pad CDP1, which intersects the horizontal direction D1 and/or D3, and an outer side surface of the corner upper dummy pad SDP2, which intersects the horizontal direction D1 and/or D3. The semiconductor device 1 illustrated in FIGS. 1 and 2 may be completed through the above-described series of processes.

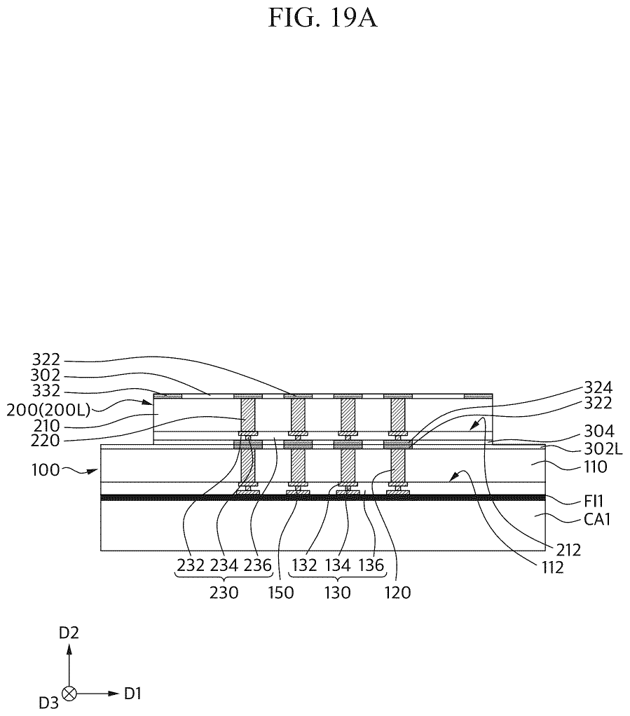

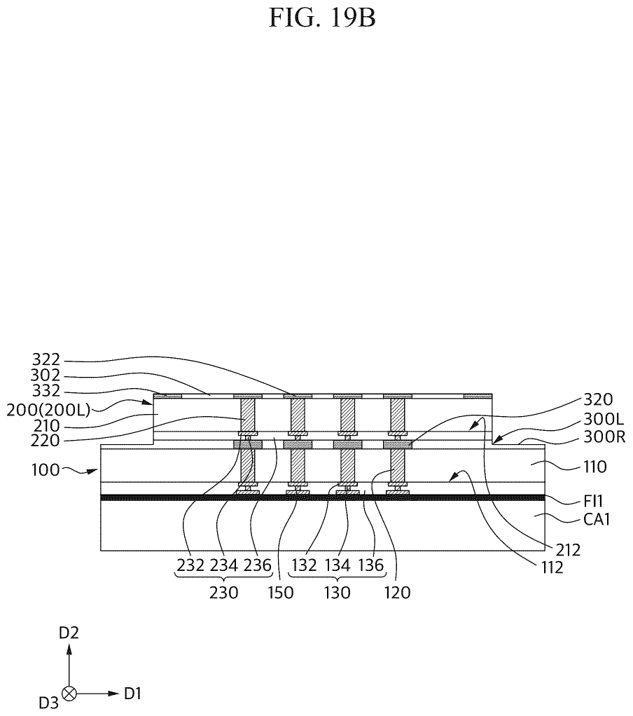

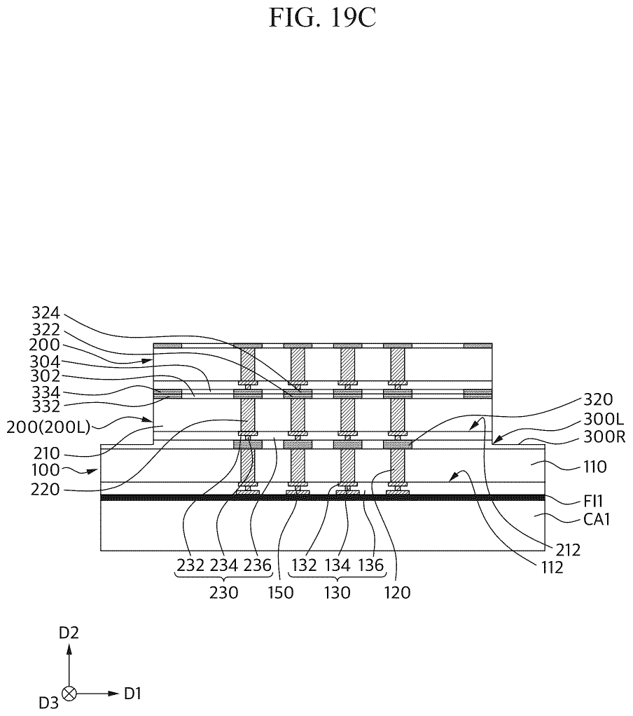

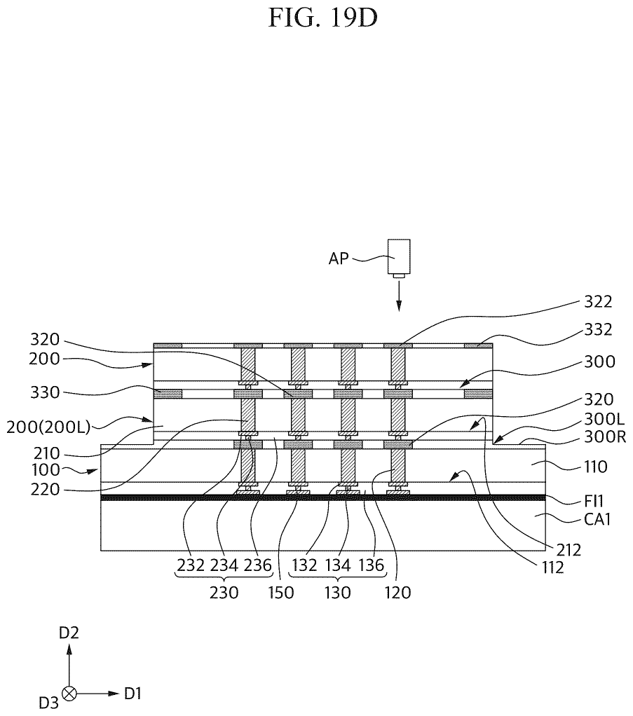

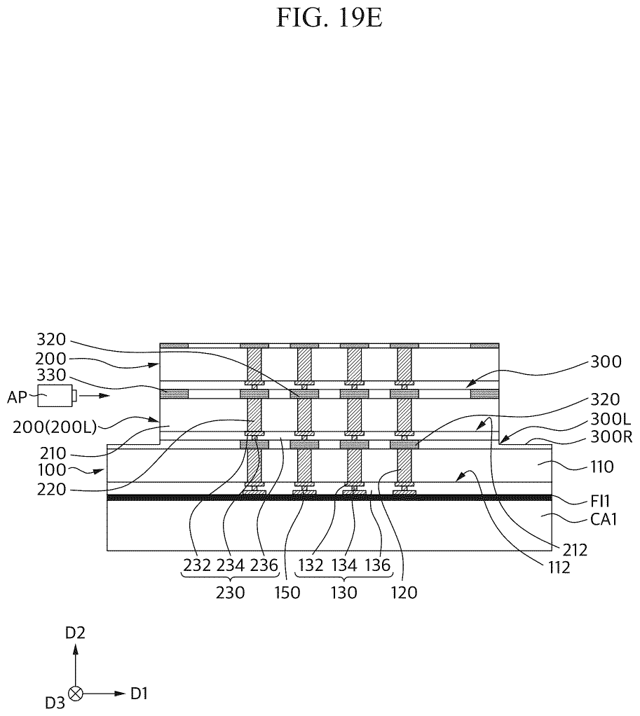

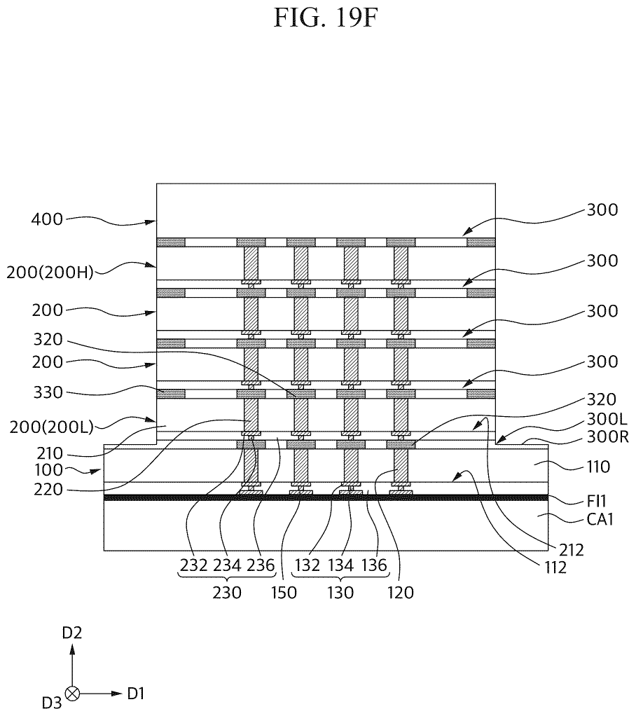

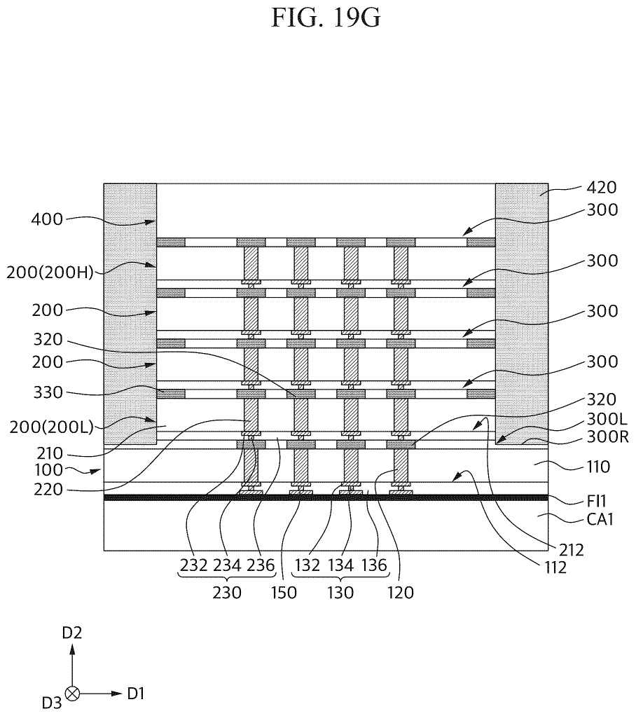

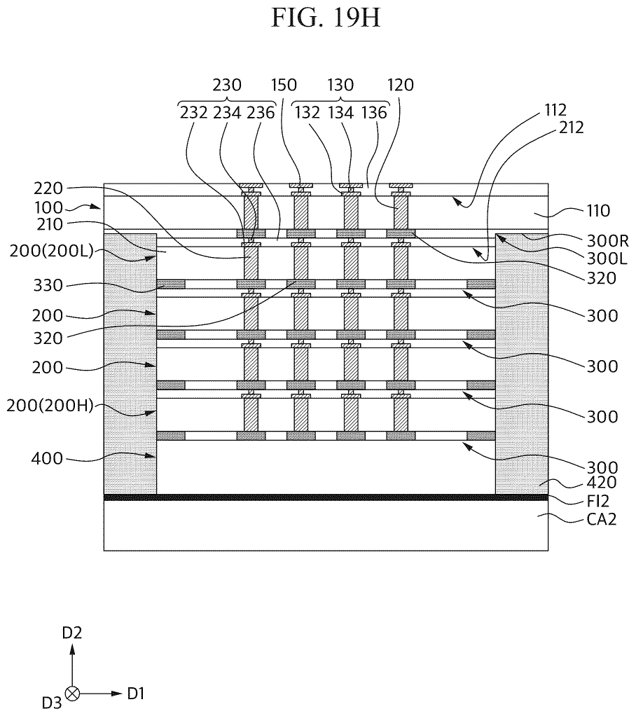

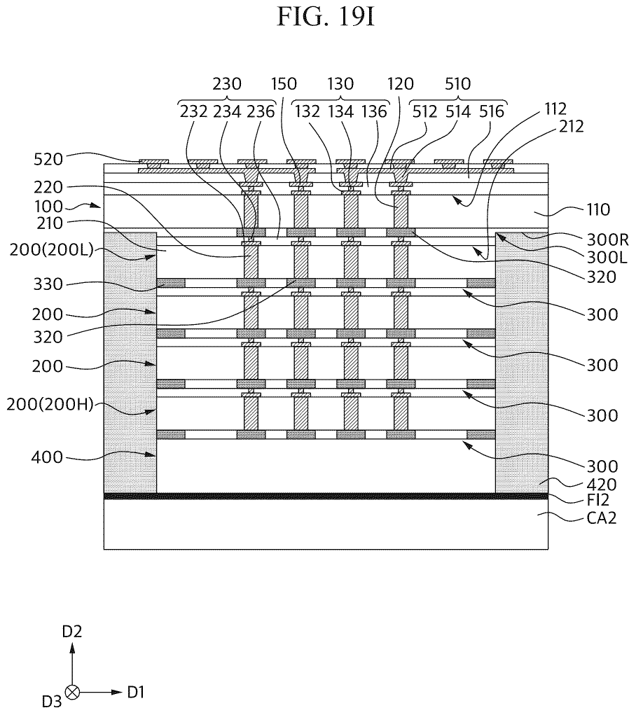

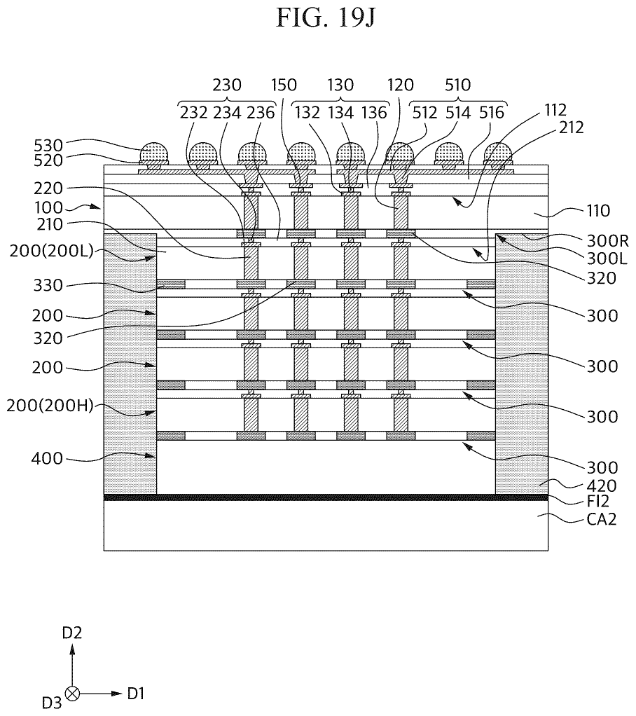

FIGS. 19A through 19I are cross-sectional diagrams sequentially illustrating processes for manufacturing a semiconductor device according to some implementations of the present disclosure.

Referring to FIG. 19A, a plurality of upper surface chip connection pads 322 and a lowermost upper surface chip coupling insulation material layer 302L may be formed on an upper surface of the first semiconductor chip 100. The plurality of upper surface chip connection pads 322 may be disposed on the upper surface, namely, an inactive surface of the first semiconductor chip 100. The plurality of upper surface chip connection pads 322 may be disposed on the upper surface of the first semiconductor chip 100 so as to be connected to the plurality of first through electrodes 120. The upper surface chip coupling insulation material layer 302 may be formed to surround side surfaces of the plurality of upper surface chip connection pads 322 on the upper surface, namely, the inactive surface of the first semiconductor chip 100. While covering the upper surface of the first semiconductor chip 100 and the side surfaces of the plurality of upper surface chip connection pads 322, the upper surface chip coupling insulation material layer 302 may not cover and may expose upper surfaces of the plurality of upper surface chip connection pads 322.

According to some implementations, the first semiconductor chip 10 with the plurality of upper surface chip connection pads 322 and the upper surface chip coupling insulation material layer 302 formed on the upper surface may be attached above a first support substrate CA1. The first semiconductor chip 100 may be attached on a first release film F11 after the first release film F11 is attached on an upper surface of the first support substrate CA1. The first semiconductor chip 100 may be attached on the first release film F11 so that the first wiring structure 130 faces the first support substrate CA1.

According to some implementations, the plurality of upper surface chip connection pads 322 and the upper surface chip coupling insulation material layer 302 may be also formed on an upper surface of the second semiconductor chip 200. The plurality of upper surface chip connection pads 322 may be disposed on the upper surface, namely, an inactive surface of the second semiconductor chip 200. The plurality of upper surface chip connection pads 322 may be disposed on the upper surface of the second semiconductor chip 200 so as to be connected to the plurality of second through electrodes 220. The upper surface chip coupling insulation material layer 302 may be formed to surround the side surfaces of the plurality of upper surface chip connection pads 322 on the upper surface, namely, the inactive surface of the second semiconductor chip 200. While covering the upper surface of the second semiconductor chip 200 and the side surfaces of the plurality of upper surface chip connection pads 322, the upper surface chip coupling insulation material layer 302 may not cover and may expose the upper surfaces of the plurality of upper surface chip connection pads 322.

According to some implementations, a plurality of lower surface chip connection pads 324 and the lower surface chip coupling insulation material layer 304 may be formed on a lower surface of the second semiconductor chip 200. The plurality of lower surface chip connection pads 324 may be disposed on the lower surface of the second semiconductor chip 200, namely, a lower surface of the second wiring structure 230. The plurality of lower surface chip connection pads 324 may be disposed on the lower surface of the second semiconductor chip 200 so as to be connected to the second wiring pattern 232 and/or the second wiring via 234. The lower surface chip coupling insulation material layer 304 may be formed to surround side surfaces of the plurality of lower surface chip connection pads 324 on the lower surface of the second semiconductor chip 200. While covering the lower surface of the second semiconductor chip 200 and the side surfaces of the plurality of lower surface chip connection pads 324, the lower surface chip coupling insulation material layer 304 may not cover and may expose lower surfaces of the plurality of lower surface chip connection pads 324.

According to some implementations, the upper surface chip coupling insulation material layer 302 which is formed on the upper surface of the first semiconductor chip among upper surface chip coupling insulation material layers 302 formed on respective upper surfaces of the first semiconductor chip 100 and the second semiconductor chip 200 may be separately referred to as the lowermost upper surface chip coupling insulation material layer 302L.

According to some implementations, the second semiconductor chip 200 may be disposed above the first semiconductor chip 100. The second semiconductor chip 200 may be the lowermost semiconductor chip 200 which is illustrated in FIG. 13. The lowermost second semiconductor chip 200L may be positioned above the first semiconductor chip 100 so that the second wiring structure 230 faces the first semiconductor chip 100. The lowermost second semiconductor chip 200L may be positioned above the first semiconductor chip 100 so that the plurality of lower surface chip connection pads 324 which is formed on a lower surface of the lowermost second semiconductor chip 200L corresponds to the plurality of upper surface chip connection pads 322 which is formed on the upper surface of the first semiconductor chip 100. For example, each of the plurality of upper surface chip connection pads 322 and the plurality of lower surface chip connection pads 324 may be formed of a material including Cu.

According to some implementations, the lower dummy pad 332 may be positioned in an outer region in the upper surface chip coupling insulation material layer 302. The upper surface chip coupling insulation material layer 302 may cover an inner side surface of the lower dummy pad 332, but may not cover and may expose an outer side surface thereof. The upper surface chip coupling insulation material layer 302 may expose an upper surface of the lower dummy pad 332. As illustrated in FIGS. 1 and 2, the outer side surface of the lower dummy pad 332 may be aligned with an outer side surface of the upper surface chip coupling insulation material layer 302. The lower dummy pad 332 may correspond to the side lower dummy pad SDP1 and the corner lower dummy pad CDP1 of FIG. 1. The upper surface chip coupling insulation material layer 302 may correspond to the lower bonding insulation layer BL1 of FIG. 1.

According to some implementations, the lower dummy pad 332 may not be electrically connected to the second through electrode 220. The lower dummy pad 332 may not be electrically connected to the second semiconductor device 212 in the second semiconductor chip 200. Since being not electrically connected to the second through electrode 220, the lower dummy pad 332 may not be electrically connected also to the first semiconductor chip 100.

Referring to FIGS. 19A and 19B, heat and/or pressure may be applied in a process of positioning the lowermost second semiconductor chip 200L above the first semiconductor chip 100, so that the plurality of upper surface chip connection pads 322 and the plurality of lower surface chip connection pads 324 may be bonded, and so that the upper surface chip coupling insulation material layer 302 and the lower surface chip coupling insulation material layer 304 may be bonded. In some implementations, while forming a covalent bond, the plurality of upper surface chip connection pads 322 and the upper surface chip coupling insulation material layer 302 may be bonded to the plurality of lower surface chip connection pads 324 and the lower surface chip coupling insulation material layer, respectively. For example, in a process of positioning the second semiconductor chip 200 above the first semiconductor chip 100, heat of a first temperature may be applied.

According to some implementations, the upper dummy pad 334 may be positioned in an outer region in the lower surface chip coupling insulation material layer 304. The lower surface chip coupling insulation material layer 304 may cover an inner side surface of the upper dummy pad 334, but may not cover and may expose an outer side surface thereof. As illustrated in FIGS. 1 and 2, the outer side surface of the upper dummy pad 334 may be aligned with an outer side surface of the lower surface chip coupling insulation material layer 304. The upper dummy pad 334 may correspond to the side upper dummy pad SDP2 and the corner upper dummy pad CDP2 of FIG. 1. The lower surface chip coupling insulation material layer 304 may correspond to the upper bonding insulation layer BL2 of FIG. 2. Then, heat of a second temperature higher than the first temperature may be applied, so that the plurality of bonding pads 320 in which the plurality of upper surface chip connection pads 322 and the plurality of lower surface chip connection pads 324 corresponding to each other are coupled and the chip coupling insulation layer 300 in which the upper surface chip coupling insulation material layer 302 and the lower surface chip coupling insulation material layer 304 may be coupled. The chip coupling insulation layer 300 which is interposed between the first semiconductor chip 100 and the lowermost second semiconductor chip 200L may be separately referred to as the lowermost chip coupling insulation layer 300L. The plurality of upper surface chip connection pads 322 and the plurality of lower surface chip connection pads 324 corresponding to each other may be expanded by heat to be in contact with each other and then, through diffusion of included metallic atoms, may become the plurality of bonding pads 320 each of which is diffusion-bonded to be integrally formed.

Referring to FIGS. 19C and 19D, the second semiconductor chip 200 may be positioned above the lowermost second semiconductor chip 200L. The plurality of lower surface chip connection pads 324, the upper dummy pad 334, and the lower surface chip coupling insulation material layer 304 may be formed on lower surfaces of the plurality of second semiconductor chips 200 which is positioned above the lowermost second semiconductor chip 200L.

According to some implementations, the lower surface chip connection pad 324 may be attached to the upper surface chip connection pad 322 of the lowermost second semiconductor chip 200L, and the lower surface chip coupling insulation material layer 304 may be attached to the upper surface chip coupling insulation material layer 302. In addition, the upper dummy pad 334 may be attached to the lower dummy pad 332.

In some implementations, when the upper surface chip connection pad 322 and the lower surface chip connection pad 324 are offset from each other in the horizontal direction D1 and/or D3, the lower surface chip connection pad 324 and the upper dummy pad 334 may be attached to a portion of the upper chip coupling insulation material layer 302. Also, the upper surface chip connection pad 322 and the lower dummy pad 332 may be attached to a portion of the lower surface chip coupling insulation material layer 304.

Afterward, in a way similar to the above description with reference to FIG. 19B, the plurality of bonding pads 320 in which the plurality of upper surface chip connection pads 322 and the plurality of lower surface chip connection pads 324 corresponding to each other are coupled to each other and the chip coupling insulation layer 300 in which the upper surface chip coupling insulation material layer 302 and the lower surface chip coupling insulation material layer 304 are coupled may be formed between the lowermost second semiconductor chip 200L and the second semiconductor chip 200, so that the plurality of second semiconductor chips 200 may be attached in sequential order above the first semiconductor chip 100. Also, the dummy pad 330 in which the lower dummy pad 332 and the upper dummy pad 334 corresponding to each other are coupled to each other may be formed between the lowermost second semiconductor chip 200L and the second semiconductor chip 200.

According to some implementations, in a process of positioning the second semiconductor chip 200 above the lowermost second semiconductor chip 200L, the heat and/or pressure based on the first temperature may be applied, so that the lower dummy pad 332 and the upper dummy pad 334 also may be bonded together. In some implementations, the lower dummy pad 332 and the upper dummy pad 334 also may be bonded together while forming a covalent bond. Then, the dummy pad 330 in which the lower dummy pad 332 and the upper dummy pad 334 corresponding to each other are coupled to each other also may be formed by the heat of the second temperature higher than the first temperature. An outer side surface of the formed dummy pad 330 may be exposed to outsides of the second semiconductor chip 200 and the chip coupling insulation layer 300.

Then, similarly to the method described above with reference to FIG. 18E, a position of the dummy pad 330 may be identified by using the measurement device AP. A position of the dummy pad 330 may be indirectly identified based on a structure or patterns formed on the upper surface of the second semiconductor chip 200. For example, one of the patterns may be the upper surface chip connection pad 322 and the lower dummy pad 332.

Referring to FIG. 19E, similarly to the method described above with reference to FIG. 18F, a misalignment value generated in a process in which the second semiconductor chip 200 is stacked above the lowermost second semiconductor chip 200L may be measured by using the measurement device AP. Since a process of obtaining the misalignment value by using the measurement device has been described in detail with reference to FIGS. 5 through 7, a detailed description thereof will be omitted below.

Referring to FIG. 19F, the plurality of second semiconductor chips 200 may be positioned above a product of FIG. 19E in sequential order. The plurality of lower surface chip connection pads 324 (see FIG. 19C), the upper dummy pad 334 (see FIG. 19C), and the lower surface chip coupling insulation material layer 304 (see FIG. 19C) may be formed on the lower surfaces of the plurality of second semiconductor chips 200 which is positioned in sequential order. The plurality of upper surface chip connection pads 322 (see FIG. 19C), the lower dummy pad 332 (see FIG. 19C), and the upper surface chip coupling insulation material layer 302 may be formed on the upper surface of the second semiconductor chip 200.

Afterward, in a way similar to the above description with reference to FIG. 19B, the plurality of bonding pads 320 in which the plurality of upper surface chip connection pads 322 and the plurality of lower surface chip connection pads 324 corresponding to each other are coupled to each other, the dummy pad 330 in which the upper dummy pad 334 and the lower dummy pad 332 are coupled to each other, and the chip coupling insulation layer 300 in which the upper surface chip coupling insulation material layer 302 and the lower surface chip coupling insulation material layer 304 are coupled may be formed between the plurality of second semiconductor chips 200, so that the plurality of second semiconductor chips 200 may be attached in sequential order.

Then, the support dummy substrate 400 may be stacked on the uppermost second semiconductor chip 200H.

Referring to FIG. 19G and FIG. 19H, the molding layer 420 which covers the upper surface of the first semiconductor chip 100 and surrounds side surfaces of the plurality of second semiconductor chips 200 and the support dummy substrate 400 may be formed above the first semiconductor chip 100.

According to some implementations, after the molding layer 420 is formed, the first support substrate CA1 to which the first release film F11 is attached may be separated from the first semiconductor chip 100. A product of FIG. 19G, from which the first support substrate CA1 is separated, may be attached to a second support substrate CA2 to which a second release film F12 is attached. At this point, the product of FIG. 19G may be attached to the second support substrate CA2 so that the support dummy substrate 400 faces the second release F12. The first wiring structure 130 may be positioned to face in the second direction D2.

Referring to FIG. 19I, the base redistribution layer 510 may be formed on the first wiring structure 130 of the first semiconductor chip 100. The base redistribution layer 510 may be formed to include the plurality of redistribution line patterns 512, the plurality of redistribution vias 514, and a redistribution insulation layer 516. At least a portion of the plurality of redistribution vias 514 or at least a portion of the plurality of redistribution line patterns 512 may be formed to be in contact with the plurality of chip pads 150. The redistribution line pattern 512 which is disposed on an upper surface of the base redistribution layer 510 among the plurality of redistribution line patterns 512 may be referred to as the redistribution pad 520.

In some implementations, the plurality of redistribution vias 514 may have a tapered shape of which a horizontal width is extended while being widened in a direction from bottom to top. In other words, the plurality of redistribution vias 514 may be formed so that horizontal widths thereof are widened while becoming far from the first semiconductor chip 100.

Referring to FIG. 19J, the plurality of external terminals 530 may be attached to the plurality of redistribution pads 520.

Afterward, the second support substrate CA2 to which the second release film F12 is attached may be separated from the support dummy substrate 400 and the molding layer 420, and then a product thereof may be turned upside down, so that the semiconductor device 1000 illustrated in FIG. 13 may be formed.

In a semiconductor device according to some implementations of the present disclosure, semiconductor chips may be stacked in a hybrid bonding scheme. The semiconductor device may include a dummy pad disposed in an outermost region in a bonding dielectric layer to be hybrid-bonded. A side of the dummy pad may be exposed to an outside, so that a misalignment value may be measured in real time in a process of stacking the semiconductor chips. The misalignment value may include a misalignment value based on horizontal movement of a stacked semiconductor chip and a misalignment value based on rotational displacement of a stacked semiconductor chip.

In some aspects, the present disclosure provides a method of manufacturing a semiconductor device including preparing a lower chip including a lower substrate, a lower bonding pad disposed on a back surface of the lower substrate, a lower bonding insulation layer surrounding the lower bonding pad, and a lower dummy pad spaced apart from the lower bonding pad in a first direction with the lower bonding insulation layer in between, aligning, on the lower chip, an upper chip including an upper substrate, an upper bonding pad disposed on an upper surface of the upper substrate, an upper bonding insulation layer surrounding the upper bonding pad, and an upper dummy pad spaced apart from the upper bonding pad in the first direction with the upper bonding insulation layer in between, allowing, by moving the upper chip in a second direction intersecting the first direction, the lower bonding pad, the lower bonding insulation layer, and the lower dummy pad to be in contact with the upper bonding pad, the upper bonding insulation layer, and the upper dummy pad, respectively, and bonding, by applying heat, the lower bonding pad, the lower bonding insulation layer, and the lower dummy pad to the upper bonding pad, the upper bonding insulation layer, and the upper dummy pad, respectively.

In some implementations, an outer side surface of the lower dummy pad may be aligned with an outer side surface of the lower bonding insulation layer, and an outer side surface of the upper dummy pad may be aligned with an outer side surface of the upper bonding insulation layer.

In some implementations, the method may include forming a molding layer surrounding the lower chip and the upper chip, and the outer side surface of the lower dummy pad and the outer side surface of the upper dummy pad may be in contact with the molding layer.

In some implementations, the method may include obtaining a misaligned value of the upper chip on the lower chip by measuring a distance by which the upper dummy pad is offset from the bonded lower dummy pad.

In some implementations, in the obtaining of the misaligned value of the upper chip on the lower chip, an outer side surface of the upper dummy pad and an outer side surface of the lower dummy pad may be exposed to an outside.

In some implementations, in the allowing of the lower bonding pad, the lower bonding insulation layer, and the lower dummy pad to be in contact with the upper bonding pad, the upper bonding insulation layer, and the upper dummy pad, respectively, heat of a first temperature may be applied to the lower bonding pad, the upper bonding pad, the lower bonding insulation layer, the lower dummy pad, and the upper dummy pad, and in the bonding of the lower bonding pad, the lower bonding insulation layer, and the lower dummy pad to the upper bonding pad, the upper bonding insulation layer, and the upper dummy pad, respectively, heat of a second temperature higher than the first temperature may be applied to the lower bonding pad, the upper bonding pad, the lower bonding insulation layer, the lower dummy pad, and the upper dummy pad.

In some implementations, in the aligning of the upper chip on the lower chip, the lower bonding pad and the upper bonding pad may overlap in the second direction.

In some implementations, semiconductor chips may be stacked in a hybrid bonding scheme in a semiconductor device. The semiconductor device may include a dummy pad disposed in an outermost region in a bonding dielectric layer to be hybrid-bonded. A side of the dummy pad may be exposed to an outside, so that a misalignment value may be measured in real time in a process of stacking the semiconductor chips. The misalignment value may include a misalignment value based on horizontal movement of a stacked semiconductor chip and a misalignment value based on rotational displacement of a stacked semiconductor chip.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As described above, implementations have been disclosed in the drawings and the present disclosure. Implementations have been described with a specific term in the present disclosure, but the term is used merely to describe the technical spirit of the present disclosure, not to limit a meaning or the scope of the present disclosure described in the accompanying claims. Therefore, those skilled in the art will understand that various modifications or other equivalent implementations are possible therefrom.

What is claimed is:

1. A semiconductor device comprising:
a lower chip comprising (i) a lower bonding pad on a back surface of a lower substrate, (ii) a lower dummy pad spaced apart from the lower bonding pad in a first direction and adjacent to an outer region in the lower substrate, and (iii) a lower bonding insulation layer surrounding at least a portion of the lower bonding pad and at least a portion of the lower dummy pad;
an upper chip comprising (i) an upper bonding pad that is on a front surface of an upper substrate, wherein a front surface of the upper bonding pad faces the back surface of the lower substrate in a second direction and is in contact with a back surface of the lower bonding pad, (ii) an upper dummy pad spaced apart from the lower bonding pad in the first direction and adjacent to an outer region in the upper substrate, and (iii) an upper bonding insulation layer surrounding at least a portion of the upper bonding pad and at least a portion of the upper dummy pad; and
a molding layer surrounding the lower chip and the upper chip,
wherein an outer side surface of the lower dummy pad and an outer side surface of the upper dummy pad are in contact with the molding layer.

2. The semiconductor device of claim 1, wherein a front surface of the lower dummy pad is in contact with a back surface of the upper dummy pad.

3. The semiconductor device of claim 1, wherein a side surface of the lower dummy pad, which is opposite to the outer side surface of the lower dummy pad, is in contact with the lower bonding insulation layer.

4. The semiconductor device of claim 1, wherein the lower chip comprises a wiring insulation layer in contact with an entire front surface of the lower dummy pad.

5. The semiconductor device of claim 4, wherein
the lower chip comprises a via that is connected to a front surface opposite to the back surface of the lower bonding pad, based on the via extending into the wiring insulation layer, and
a width of the via in the first direction increases toward the upper chip.

6. The semiconductor device of claim 1, wherein the upper dummy pad is offset from the lower dummy pad in the first direction.

7. The semiconductor device of claim 1, wherein the upper bonding pad is offset from the lower bonding pad in the first direction.

8. The semiconductor device of claim 1, wherein at least a portion of the back surface of the lower dummy pad is in contact with the molding layer.

9. The semiconductor device of claim 1, wherein the lower chip comprises a wiring insulation layer in contact with a front surface opposite to the back surface of the lower dummy pad, and
an outer side surface of the wiring insulation layer is aligned with the outer side surface of the lower dummy pad.

10. The semiconductor device of claim 1, wherein the outer side surface of the lower dummy pad is inclined relative to the outer side surface of the upper dummy pad by a predetermined angle.

11. A semiconductor device comprising:
a lower chip comprising (i) a lower bonding pad on a back surface of a lower substrate, (ii) a plurality of lower dummy pads spaced apart from the lower bonding pad in a first direction and adjacent to an outer region in the lower substrate, and (iii) a lower bonding insulation layer surrounding at least a portion of the lower bonding pad and at least a portion of the plurality of lower dummy pads; and
an upper chip comprising (i) an upper bonding pad that is disposed on a front surface of an upper substrate, wherein a front surface of the upper bonding pad faces the back surface of the lower substrate in a second direction and is in contact with a back surface of the lower bonding pad, (ii) a plurality of upper dummy pads spaced apart from the upper bonding pad in the first direction and adjacent to an outer region in the upper substrate, and (iii) an upper bonding insulation layer surrounding at least a portion of the upper bonding pad and at least a portion of the plurality of upper dummy pads,
wherein outer side surfaces of the plurality of lower dummy pads are aligned with an outer side surface of the lower bonding insulation layer, and
wherein outer side surfaces of the plurality of upper dummy pads are aligned with an outer side surface of the upper bonding insulation layer.

12. The semiconductor device of claim 11, wherein widths along major axes of the plurality of upper dummy pads and widths along major axes of the plurality of lower dummy pads are within a range of 5 to 40 micrometers.

13. The semiconductor device of claim 11, wherein the plurality of upper dummy pads comprise a first corner upper dummy pad at a corner area of the front surface of the upper substrate, and
the plurality of lower dummy pads comprise a first corner lower dummy pad having a back surface in contact with a front surface of the first corner upper dummy pad.

14. The semiconductor device of claim 13, wherein the plurality of lower dummy pads comprise a side lower dummy pad between a pair of corner areas of the front surface of the upper substrate, the pair of corner areas being adjacent to one another along an edge of the upper chip, and
the plurality of upper dummy pads comprise a side upper dummy pad having a front surface in contact with a back surface of the side lower dummy pad.

15. The semiconductor device of claim 13, wherein the plurality of upper dummy pads comprise a plurality of corner upper dummy pads including the first corner upper dummy pad, and
the plurality of corner upper dummy pads comprise a pair of corner dummy pads that are spaced apart from, and perpendicular to, each other with a corner of the upper chip therebetween.

16. The semiconductor device of claim 11, wherein the plurality of upper dummy pads are electrically insulated from the lower chip.

17. The semiconductor device of claim 11, wherein a side surface of the upper chip, which intersects the first direction, is offset from a side surface of the lower chip, which intersects the first direction, in a third direction that intersects the first direction and the second direction.

18. The semiconductor device of claim 11, comprising a molding layer surrounding the lower chip and the upper chip and in contact with side surfaces of the plurality of lower dummy pads and with side surfaces of the plurality of upper dummy pads.

19. A semiconductor device comprising:
a lower chip comprising (i) a lower substrate, (ii) a lower bonding pad on a back surface of the lower substrate, (ii) a plurality of lower dummy pads spaced apart from the lower bonding pad in a first direction and adjacent to an outer region in the lower substrate, and (iii) a lower bonding insulation layer surrounding at least a portion of the lower bonding pad and at least a portion of the plurality lower dummy pads;
an upper chip comprising (i) an upper substrate having a front surface facing a back surface of the lower bonding pad, (ii) an upper bonding pad that is on the front surface of the upper substrate, wherein a front surface of the upper bonding pad faces the back surface of the lower substrate in a second direction and is in contact with the back surface of the lower bonding pad, (iii) a plurality of upper dummy pads spaced apart from the upper bonding pad in the first direction and adjacent to an outer region in the upper substrate, and (iv) an upper bonding insulation layer surrounding at least a portion of the upper bonding pad and at least a portion of the plurality of upper dummy pads; and
a molding layer surrounding the lower chip and the upper chip,
wherein the plurality of upper dummy pads comprise
a corner upper dummy pad at a corner area of the upper substrate and in contact with the molding layer, and
a side upper dummy pad between a pair of corner areas of the upper substrate that are adjacent along an edge of the upper chip,
wherein the plurality of lower dummy pads comprise
a corner lower dummy pad in contact with the molding layer and having a back surface in contact with a front surface of the corner upper dummy pad, and
a side lower dummy pad having a back surface in contact with a front surface of the side upper dummy pad.

20. The semiconductor device of claim 19, wherein a side surface of the lower substrate, which intersects the first direction, is aligned with a side surface of the corner lower dummy pad, which intersects the first direction, and
a side surface of the upper substrate, which intersects the first direction, is aligned with a side surface of the corner upper dummy pad, which intersects the first direction.
